(19) United States
(12) Patent Application Publication
(10) Pub. No.: US 2017/0096339 A1
(43) Pub. Date: Apr. 6, 2017

(54) PREPARATION OF WAFER-SCALE FILMS OF ALIGNED CARBON NANOTUBES BY VACUUM FILTRATION

(71) Applicants: Xiaowei He, Wanzhou District (CN); Weilu Gao, Rong Jing Sheng Yuan (CN); Junichiro Kono, Houston, TX (US)

(72) Inventors: Xiaowei He, Wanzhou District (CN); Weilu Gao, Rong Jing Sheng Yuan (CN); Junichiro Kono, Houston, TX (US)

(73) Assignee: William Marsh Rice University, Houston, TX (US)

(21) Appl. No.: 15/278,430

(22) Filed: Sep. 28, 2016

Related U.S. Application Data
(60) Provisional application No. 62/233,901, filed on Sep. 28, 2015.

(51) Int. Cl. B05D 5/12; B01D 61/02; C23C 16/26

(52) U.S. Cl. CPC C01B 31/0273; B01D 61/027; C23C 16/26; C01B 2202/02; C01B 2202/08; B82Y 40/00

(57) ABSTRACT

A method for preparing a film of aligned rod-like nanostructures or nanotubes comprises preparing a solution that comprises rod-like nanostructures or nanotubes, wherein the rod-like nanostructures or the nanotubes are well-dispersed, and performing vacuum filtration of the solution through a filtration membrane, wherein the vacuum filtration produces a film on the filtration membrane where the rod-like nanostructures or the nanotubes are aligned. The well-dispersed individual rod-like nanostructures or nanotubes may be separately suspended in the solution. The concentration of rod-like nanostructures or nanotubes may be below a threshold value and/or the filtration speed may be as slow as possible. Where a surfactant is utilized to aid dispersion, the surfactant concentration may be below a critical micelle concentration (CMC).

### CROSS-REFERENCE TO RELATED APPLICATIONS

This application claims the benefit of U.S. Provisional Patent Application No. 62/233,901 filed on Sep. 28, 2015, which is incorporated herein by reference.

### STATEMENT REGARDING FEDERALLY SPONSORED RESEARCH

This invention was made with government support under Grant No. DE-FG02-06ER46308 awarded by the U.S. Department of Energy. The government has certain rights in the invention.

### BACKGROUND

A variety of methods have been proposed and/or demonstrated to align carbon nanotubes (CNTs), through either spontaneous or stimulated alignment, including both post-growth and direct-growth schemes. However, these methods may have issues with CNT densities incompatibility with standard microfabrication technology, a lack of chirality selectivity, scaling problems, impractically large magnetic fields, low degrees of alignment, etc. Hence, the current state of the art fails to provide methods for producing large-area single-domain films of highly-aligned, densely-packed, and chirality-enriched carbon nanotubes (e.g., SWCNTs).

Additionally, one of the challenges in nanoscience and nanotechnology is the creation of macroscopic devices by assembling nano-objects while preserving their rich variety of extraordinary properties. For example, the one-dimensional character of electrons, phonons, and excitons in individual single-wall carbon nanotubes (SWCNTs) leads to extremely anisotropic electronic, thermal, and optical phenomena that have stimulated much interest in diverse disciplines. However, their macroscopic manifestations have been limited. Therefore, a need exists for ways to produce large-scale architectures of aligned rod-like nanostructures or nanotubes (e.g., SWCNTs).

### SUMMARY OF INVENTION

In one embodiment, a method for preparing a film of aligned rod-like nanostructures or nanotubes comprises preparing a solution that comprises rod-like nanostructures or nanotubes, wherein the rod-like nanostructures or the nanotubes are well-dispersed, and performing vacuum filtration of the solution through a filtration membrane, wherein the vacuum filtration produces a film on the filtration membrane where the rod-like nanostructures or the nanotubes are aligned. In some embodiments, the well-dispersed individual rod-like nanostructures or nanotubes are separately suspended in the solution. In some embodiments, the concentration of rod-like nanostructures or nanotubes may be below a threshold value and/or the filtration speed may be as slow as possible. In embodiments where a surfactant is utilized to aid dispersion, the surfactant concentration may be below a critical micelle concentration (CMC). In some embodiments, the speed of the vacuum filtration is 1-2 mL/hour or less. In some embodiments, the drying is performed by increasing a speed of the vacuum filtration to 10 mL/hour or greater. In some embodiments, the film is a wafer scale film with an area of 1 cm² or greater. In some embodiments, the film may be for an electronic device.

The foregoing has outlined rather broadly various features of the present disclosure in order that the detailed description that follows may be better understood. Additional features and advantages of the disclosure will be described hereinafter.

### DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIGS. 1a-1j provide various images and data pertaining to the fabrication and characterization of wafer-scale monodomain films of aligned carbon nanotubes.

FIGS. 2a-2f provide various data relating to the characterization of aligned carbon nanotube films through polarization-dependent optical spectroscopy.

FIGS. 3a-3f show photographs and data for optoelectronic devices made from aligned and (6,5)-enriched carbon nanotube films.

FIGS. 4a-4e show schematics, photographs, and data for electronic devices made from aligned carbon nanotube films.

FIG. 5 provides a scheme for obtaining single crystals of carbon nanotubes, including a chirality-mixed crystal (top) and chirality-enriched crystals (bottom), such as semiconducting (6,5), metallic (6,6), and quasi-metallic (7,4) crystals.

FIG. 6 shows a SEM image of the polycarbonate filter membrane with 100 nm pore size.

FIGS. 7a-b are optical images taken in the cross-polarized mode for an aligned arc-discharge (P2-SWNT) CNT film on a quartz substrate.

FIGS. 8a-d show (a) arc-discharge (P2-SWNT) dispersed in SDBS surfactant; (b) Tuball CNTs dispersed in DOC surfactant; (c) Arc-discharge (P8-SWNT) dispersed in nanopure water; and (d) CoMoCAT (CG200) dispersed in DOC surfactant.

FIGS. 9a-b show (a) a SEM image of a FIB-prepared slab for HRTEM, and (b) a cross-sectional TEM image of an aligned carbon nanotube film with high magnification.

FIGS. 10a-f show polarized Raman Spectra of aligned films made from different types of CNTs.

FIGS. 11a-d show THz transmission spectra of aligned CNT films made by different types of CNTs.

FIGS. 12a-g show AFM images of seven CNT samples used in this study.

FIGS. 13a-g show length distribution of seven CNT samples used in the work.

FIGS. 14a-d show thickness characterization of CNT films.

FIG. 15 is an XPS spectrum from an aligned CNT film with ˜50 nm thickness, transferred onto a SiO₂/Si substrate after thoroughly washing by acetone and nanopure water.

FIGS. 16a-c show (a) photograph and (b) optical absorption spectrum of a semiconductor-enriched CNT suspension separated from arc-discharge P2-SWNT, and (c) SEM image of an aligned film made from semiconductor-enriched P2-SWNT. The red arrow shows the direction of CNT alignment.

FIGS. 17a-17b show (a) X-ray photoelectron spectroscopy of a PVP-coated and PVP-free filter membrane, and (b) The absorption angular dependence of CNT films under a linearly polarized laser beam (660 nm).

FIG. 18 shows a schematic diagram of the formation of CNT alignment in a confined region near the surface of the filter membrane.

FIGS. 19a-b show (a) an AFM image of filter membrane surface used in the work; and (b) an AFM image of filter membrane surface after the deposition of a thin layer of aligned CNT film.

FIGS. 20a-b show (a) the LD^{r} of CNT films (CG 200) as a function of surfactant (DOC) concentration, and (b) SEM image of a film made from a CNT suspension with 0.35% DOC concentration.

FIGS. 21a-c show the influence of the filtration speed on CNT alignment, or more particularly (a) a SEM image of the sample at a slow filtration speed (1 mL/hour); (b) the sample at a high filtration speed (5 mL/hour); and (c) the angular dependence of CNT film absorption under a polarized laser beam (660 nm).

FIGS. 22a-b show the alignment dependence on the concentration of CNTs (CG200), or more particularly (a) absorption spectra of CNT suspensions with different concentrations (Inset: CNT suspensions with decreasing concentration from 30 μg/mL to 4 μg/mL) and (b) the LD^{r} value of aligned CNT films as a function of CNT concentration.

FIGS. 23a-b show (a) absorption spectra of HiPco SWCNT suspensions with (red) and without (black) the removal of small diameter tubes, and (b) the absorption angular dependence of CNT films made by original sample (red) and sorted sample (black) under a polarized laser beam (660 nm).

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that comprise more than one unit unless specifically stated otherwise.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

In some embodiments, methods of fabricating films of aligned rod-like nanostructures or nanotubes are performed on a large scale. In some embodiments, the methods include a step of dispersing carbon nanotubes to form a suspension (e.g., a solution) of well-dispersed rod-like nanostructures or nanotubes. Thereafter, the well-dispersed rod-like nanostructures or nanotubes are filtered onto a membrane (e.g., through vacuum filtration) to result in the formation of an aligned rod-like nanostructures or nanotube film on the membrane. In some embodiments, the rod-like nanostructures or nanotube film may be transferred onto a substrate. In some embodiments, the rod-like nanostructures or nanotube film may be patterned. In some embodiments, the rod-like nanostructures or nanotube film may be incorporated as a component of an electrical device.

The methods of the present disclosure can have numerous variations. As nonlimiting examples, the step of preparing a nanotube/nanostructure solution or dispersing rod-like nanostructures or nanotubes can occur in the presence or absence of surfactants. In some embodiments, surfactant concentrations are kept below the critical micelle concentration (CMC). In some embodiments, the step of preparing the solution may involve dispersing the rod-like nanostructures or nanotubes in any suitable solution, such as pure water, surfactant solutions, or organic solvents. In some embodiments, rod-like nanostructure or nanotube dispersion involves sonication. In some embodiments, rod-like nanostructure or nanotube dispersion occurs by dispersing a powder of rod-like nanostructures or nanotubes with surfactant in water to create an aqueous suspension (e.g., solution) using tip sonication and ultra-centrifugation (See, e.g., Journal of Physical Chemistry B 107 (2003), pp. 13357-13367). In some embodiments, a well-dispersed rod-like nanostructure or nanotube suspension (e.g., solution) can be made by directly dissolving a water-soluble functionalized rod-like nanostructure or nanotube powder (of any type of functionality) in water (See, e.g., Accounts of Chemical Research 35 (2002), pp. 1096-1104). In some embodiments, the nanotube/nanostructure solution may be considered to be well-dispersed when individual nanotubes/nanostructures are separately suspended in the solution. Any other methods that can produce well-dispersed rod-like nanostructure or nanotube suspensions or solutions can also be utilized. In some embodiments, a concentration of the nanotube/nanostructure in the solution may be 15 μg/mL or less.

The methods of the present disclosure can utilize various types of rod-like nanostructures or nanotubes to form films. As the methods discussed herein are applicable to any type of nanotubes or rod-like nanostructures, the term “nanotubes” or “carbon nanotubes” as utilized herein shall be understood to include rod-like nanostructures or the like. For instance, in some embodiments, the carbon nanotubes include, without limitation, single-wall carbon nanotubes (SWCNTs), multi-wall carbon nanotubes (MWCNTs), metallic carbon nanotubes, semiconducting carbon nanotubes, carbon nanotube analogs, and combinations thereof. In some embodiments, the carbon nanotubes include SWCNTs.

In some embodiments, the carbon nanotubes may include various diameters and chiralities. Moreover, the carbon nanotubes may be synthesized by various methods. Examples of such methods can include, without limitation, high-pressure carbon monoxide conversion (HiPco), the CoMoCAT® method, chemical vapor deposition (CVD) methods, arc discharge methods, and other similar methods.

In some embodiments, the carbon nanotubes may include carbon nanotube analogs. In some embodiments, the carbon nanotube analogs may include any species and/or any high aspect-ratio, rod-like nanostructures. In some embodiments, the carbon nanotube analogs include, without limitation, nanowires, semiconductor nanowires, boron nitride nanotubes, transition metal dichalcogenide nanotubes, and combinations thereof. In some embodiments, the degree of alignment may be independent on the size of the nanotubes or rod-like nanostructures, such as the diameters.

Various carbon nanotube concentrations may be utilized in a solution or suspension. For instance, in some embodiments, the carbon nanotube concentration in a suspension or a solution is below the minimal value required for driving a three-dimensional liquid crystal phase transition, which is widely believed to be able to align carbon nanotubes in a suspension.

The methods discussed herein can also utilize various vacuum filtration methods to produce a film of aligned rod-like nanostructures or nanotubes, such as on the filtration membrane. See, e.g., Science 305 (2004), pp. 1273-1276. For instance, in some embodiments, the carbon nanotube suspension may be poured through a funnel (e.g., a filtration funnel) with a membrane. In some embodiments, the membrane may be hydrophilic or have a hydrophilic coating. In some embodiments, the membrane may have nanopores, micropores, macropores, and combinations thereof. In some embodiments, the membrane is a porous membrane with pore sizes of tens of nanometers. In some embodiments, the membrane has pores sized from 50 nm to 200 nm. In some embodiments, the membrane has the shape of a paper, such as a filter paper. In some embodiments, the membrane has a negative charge. In some embodiments, a speed of the vacuum filtration may be 1-2 mL/hour or less. In some embodiments, drying the film may be performed by increasing a speed of the vacuum filtration to 10 mL/hour or greater.

In some embodiments, the carbon nanotube dispersion is added to a membrane in a single aliquot. In some embodiments, the carbon nanotube dispersion is added to a membrane in multiple aliquots. In some embodiments, the filtration speed is adjusted in order to maximize carbon nanotube alignment.

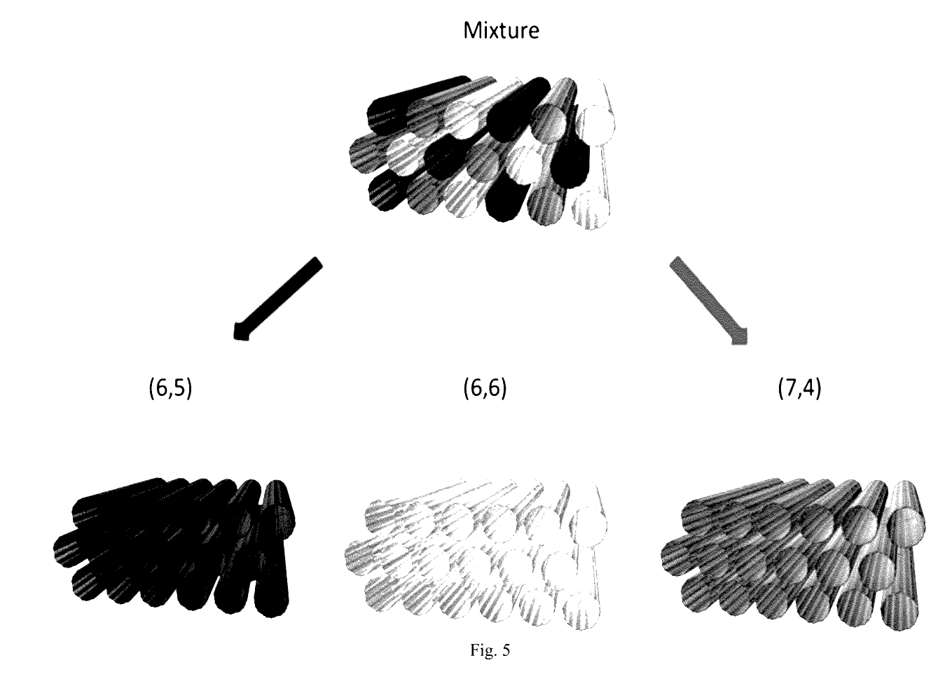

In some embodiments, a differential pressure across a membrane pushes the solution slowly through the pores, leaving carbon nanotubes on the membrane. In some embodiments, the filtration speed is kept low. In some embodiments, the vacuum filtration results in the spontaneous alignment of carbon nanotubes. In some embodiments, the spontaneous carbon nanotube alignment occurs in a two-dimensional manner. As a nonlimiting example, after filtration via the methods discussed herein, the rod-like nanostructures or nanotubes may be aligned so that the central axes passing through the center of the nanotubes are approximately parallel (e.g. FIG. 5) to form the film. In some embodiments, the rod-like nanostructures or nanotubes may demonstrate a high degree of alignment, such as S˜1, where S is a nematic order parameter. In some embodiments, the rod-like nanostructures or nanotubes of the film have a global angle standard deviation of 2 degrees or less. In some embodiments, the film produced is densely packed with 10⁶ rod-like nanostructures/nanotubes or greater in a cross-sectional area of 1 μm². In some embodiments, the methods of the present disclosure attain carbon nanotube alignment spontaneously and without utilizing any external factors or forces, such as magnetic fields or printing (e.g., inkjet printing).

In some embodiments, spontaneous alignment of rod-like nanostructures or nanotubes based on a liquid-crystal phase transition (i.e., into the nematic phase) is obtained during vacuum filtration. In some embodiments, such alignment is attained once one or more of the following conditions are met: (i) the carbon nanotube solution needs to be well-dispersed to the single-tube level (i.e., individual carbon nanotubes have to be separately suspended in the solution); (ii) if a surfactant-assisted method is used to disperse carbon nanotubes, then the surfactant concentration needs to be below the critical micelle concentration (CMC); (iii) the concentration of carbon nanotubes needs to be below a threshold value; (iv) the filtration speed needs to be as slow as possible; and/or (v) the drying process of the film needs to be fast in order to avoid any damage. When the above conditions are met, a wafer-scale, uniform carbon nanotube film with a readily controllable thickness can be formed on a membrane (e.g., a filter paper). In some embodiments, the film may have an area of 1 cm² or greater.

In some embodiments, the methods can control the thickness of the formed films by varying one or more parameters. In some embodiments, the thickness of the film can be controlled by the filtration volume, nanotube concentration in the nanotube solution, and combinations thereof. For instance, in some embodiments, the film thickness is controllable from about 1 nm to about 100 nm. In some embodiments, the methods can be utilized to precisely control the thickness of the formed films from atomic to macroscopic scale.

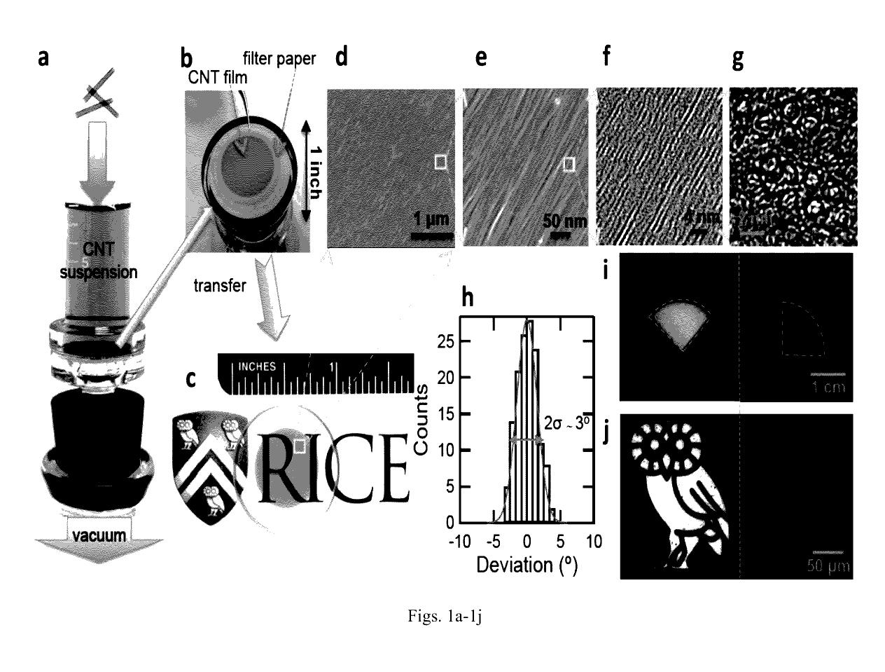

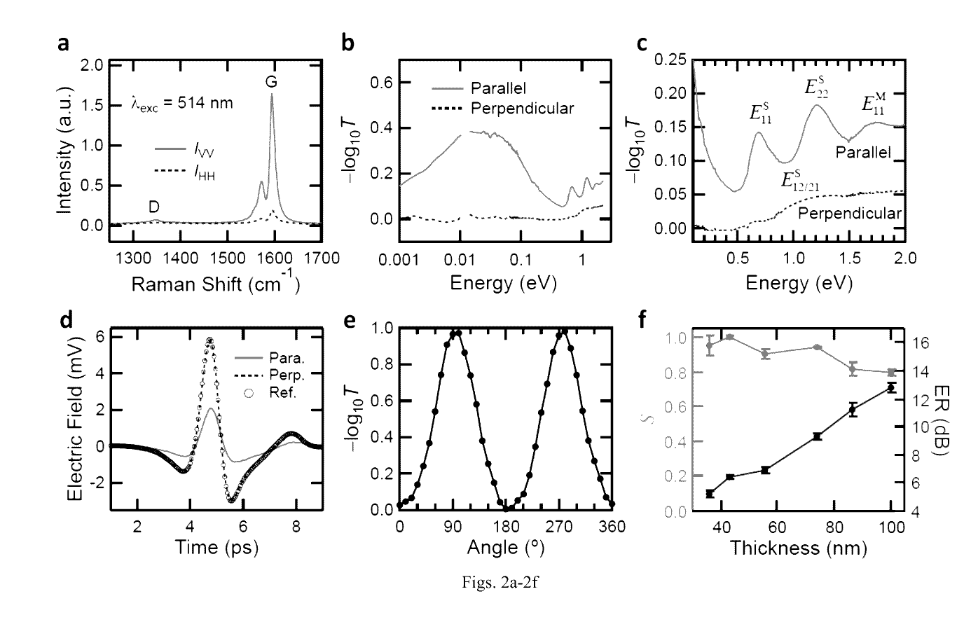

In some embodiments, vacuum filtration occurs by a “controlled differential pressure filtration (CDPF)” method that is illustrated in FIGS. 1A-B and described in more detail in the Examples section. FIG. 1A shows that a CNT suspension goes through a standard vacuum filtration system. For spontaneous CNT alignment to occur in this example, the filtration speed is preferably kept low, and the CNTs may be well dispersed in the suspension. As shown, a carbon nanotube suspension is poured into the filtration funnel with a small-pore-size filter paper. Thereafter, a differential pressure across the filter paper pushes the suspension slowly through the pores, leaving carbon nanotubes on the filter membrane. In some embodiments, the pressure difference across the filtration membrane is precisely controlled in order to precisely control the filtration speed at different stages. In some embodiments, the surfactant concentration and the CNT concentration in the original suspension are also precisely controlled in order to form a wafer•scale, uniform, and aligned carbon nanotube film on the filter paper. FIG. 1b shows that a wafer-scale, uniform CNT film is formed on the filter membrane. FIG. 1c is an optical image of the produced film after being transferred to a transparent substrate by dissolving the filter membrane. FIGS. 1d-f show a scanning electron microscopy image (FIG. 1d) a high-resolution scanning electron microscopy image (FIG. 1e), and a top-view transmission electron microscopy image (FIG. 1f) of the film, showing strong alignment and high density. FIG. 1g shows a high-resolution cross-sectional transmission electron microscopy image, further showing a high cross-sectional areal density of ˜10⁶/μm². FIG. 1h shows an angular distribution of CNTs within a 1 cm² area of the film, with a standard deviation of 1.5°, as determined by SEM image analysis. The film is opaque to light polarized parallel to the CNT alignment direction and transparent to light polarized perpendicular to the alignment direction on a macroscopic scale (FIG. 1i) and a microscopic scale (FIG. 1j). Note also that the film can be easily patterned using conventional photolithography techniques, as shown in FIG. 1j.

Moreover, different diameter carbon nanotubes may require different filter paper pore sizes, different filtration speeds, and different carbon nanotube concentrations. As such, wafer•scale semitransparent films of aligned carbon nanotubes can be produced when these parameters are optimized, as shown in FIGS. 1b-c. The scanning electron microscopy (SEM) and transmission electron microscopy (TEM) images in FIGS. 1d-f show perfect alignment with a global angle standard deviation less than 2 degrees, as shown in FIG. 1h. The cross-sectional TEM image shown in FIG. 1g indicates a well•defined hexagonal packing pattern.

In some embodiments, the formed carbon nanotube films of the present disclosure can be transferred onto another substrate. In some embodiments, formed carbon nanotube films can be transferred to an arbitrary substrate for specific applications by dissolving the membrane (e.g., filter paper) in a proper solvent.

In some embodiments, the formed carbon nanotube films can be patterned. In some embodiments, patterning occurs by using conventional photolithography techniques.

The methods of the present disclosure can be utilized to form various types of large scale films of aligned carbon nanotubes. Additional embodiments of the present disclosure pertain to the large scale films of aligned carbon nanotubes (also referred to as films).

In some embodiments, the films of the present disclosure are in an inch-size scale. In some embodiments, the films of the present disclosure have surface areas that range from about 1 mm² to about 1 cm². In some embodiments, the films of the present disclosure have surface areas that are more than about 1 cm². In some embodiments, the films of the present disclosure are macroscopic. In some embodiments, at least one of the dimensions of the films of the present disclosure is one centimeter or larger (i.e., “wafer-scale”, as used herein).

In some embodiments, the films of the present disclosure have a strong carbon nanotube alignment and a high carbon nanotube density. For instance, in some embodiments, the carbon nanotubes in the films of the present disclosure contain at least about 10⁶ nanotubes in a cross-sectional area of at least about 1 μm². In some embodiments, the carbon nanotubes in the films of the present disclosure have an S alignment value of about 1.

In some embodiments, the films of the present disclosure have a thickness ranging from about 1 nm to several micrometers. In some embodiments, the films of the present disclosure have a thickness ranging from about 1 nm to about 100 nm. In some embodiments, the films of the present disclosure are transparent or semi-transparent. In some embodiments, the films of the present disclosure are in the form of three-dimensional crystals that include single-chirality carbon nanotubes.

In some embodiments, the carbon nanotubes in the films of the present disclosure are in monodomain or single-domain form or the CNT film has approximately all the CNTs aligned the same way throughout the film. In some embodiments, the carbon nanotubes in the films of the present disclosure lack any surfactants. In some embodiments, the carbon nanotubes in the films of the present disclosure lack any residual metallic tubes, which are known to be efficient photoluminescence quenchers when in contact with semiconducting nanotubes.

In some embodiments, the carbon nanotubes in the films of the present disclosure are selected by type, by chirality, or combinations thereof. For instance, in some embodiments, the films of the present disclosure contain large-area single-domain films of highly-aligned, densely-packed, and chirality-enriched carbon nanotubes (e.g., SWCNTs).

In some embodiments, the films of the present disclosure include single-chirality ensembles of carbon nanotubes. In some embodiments, the films of the present disclosure include single crystals of carbon nanotubes. In some embodiments, the films of the present disclosure include wafer•scale single crystals of single-chirality carbon nanotubes. In some embodiments, “single crystals” refers to the existence of a continuous and unbroken periodic array with well•defined translational symmetry in which carbon nanotubes are perfectly aligned and packed in all three spatial directions. In some embodiments, “single-chirality” indicates that the crystal is comprised of only one species of carbon nanotubes having the same chiral indices, (n,m). In some embodiments, the carbon nanotubes in the films of the present disclosure include, without limitation, single crystals of metallic carbon nanotubes, single crystals of semiconducting carbon nanotubes, single crystals of single-chirality semiconducting carbon nanotubes with desired bandgaps, and combinations thereof.

In some embodiments, the films of the present disclosure include carbon nanotubes with a hexagonal crystalline pattern. In some embodiments, the carbon nanotubes in the films of the present disclosure are in “crystalline” form. In some embodiments, the term “crystalline” requires perfect periodicity with a well•defined aligned pattern. In some embodiments, the carbon nanotubes in the films of the present disclosure are enriched to a single chirality.

In some embodiments, the films of the present disclosure can be fabricated into electronic devices. Further embodiments of the present disclosure pertain to electronic devices that contain the films of the present disclosure. In some embodiments, the electronic devices of the present disclosure include, without limitation, optoelectronic devices, photodetectors, Hall-bar devices, field effect transistors, terahertz polarizers, terahertz/infrared polarizers using metal-semiconductor mixed carbon nanotubes, thin-film transistors, thin-film transistors using semiconducting carbon nanotubes, polarized photoluminescence devices, polarized light emission devices (e.g., light emitting diodes and laser diodes) using semiconducting carbon nanotubes, polarization-sensitive electro-optic modulators, polarization-sensitive carbon nanotubes detectors (e.g., in a wide wavelength range from the far-infrared to the ultraviolet), electrical cables (e.g., electrical cables made of aligned ‘armchair quantum wires’ with high strength and conductivity for power transmission using single crystals of armchair carbon nanotubes), polarization-sensitive photodetectors (e.g., photodetectors in an ultrawide wavelength range from the terahertz to the ultraviolet using single crystals of semiconducting carbon nanotubes and their heterostructures), saturable absorbers for ultrafast lasers (e.g., from the visible to the infrared range using single crystals of single-chirality carbon nanotubes, high mechanical strength carbon nanotube sheets, fibers, and composites using single crystals of carbon nanotubes), high performance electrodes (e.g., for use as fuel cells, solar cells, and high•performance materials for hydrogen storage using single crystals of carbon nanotubes), and combinations thereof.

### Advantages and Applications

In some embodiments, the present disclosure provides a new process to produce a wafer-scale (e.g., inch-sized) film with an adjustable thickness of aligned carbon nanotubes. The methods of the present disclosure are universal. Furthermore, the methods of the present disclosure are applicable to any carbon nanotube species and/or any high aspect-ratio, rod-like nanostructures, including semiconductor nanowires and boron nitride nanotubes.

Since the methods of the present disclosure are applicable to all species of carbon nanotubes, both metallic and semiconducting, with any diameter or chirality, and irrespective of the synthesis method, the methods of the present disclosure have a diverse range of potential applications in various electronic devices (as previously described). For instance, one can create the most appropriate single crystals of carbon nanotubes with tailored optical absorption and emission properties desired for specific optoelectronic applications.

In some embodiments, the methods of the present disclosure solve a problem of aligning carbon nanotubes on a large scale in a simple and universal way. Individual carbon nanotubes have been shown to possess many unique properties that are promising for various applications in nanotechnology. However, macroscopic assemblies of carbon nanotubes have so far shown only poor properties because of the lack of alignment of carbon nanotubes. In contrast, the methods discussed herein based on vacuum filtration provide a uniform, large-scale carbon nanotube film with a high degree of alignment in a well-controlled, simple, and reproducible manner, regardless of the type, diameter, or chirality of the carbon nanotubes used.

Another advantage of the methods of the present disclosure over the conventional vacuum filtration methods is the ability to align carbon nanotubes while (i) being independent of carbon nanotube types, chiralities and growth methods; (ii) producing wafer-scale carbon nanotube films; (iii) providing a simple method of use; (iv) providing high density carbon nanotubes; (v) providing control over thickness; and/or (vi) providing ease with which to perform photolithography to fabricate devices. As set forth previously, such advantages can be obtained through the following three steps: (1) preparation of a well-dispersed carbon nanotube solution or suspension; (2) vacuum filtration to produce an aligned carbon nanotube film on filter paper; and/or (3) transfer of the carbon nanotube film onto arbitrary substrates.

In some embodiments, the methods of the present disclosure can be easily scaled up for industrial manufacturing. In more specific embodiments, the methods of the present disclosure provide uniform, wafer-scale (e.g., >cm²) carbon nanotube (e.g., SWCNT) films of an arbitrarily and precisely controllable thickness (e.g., from 1 nm to ˜100 nm) with a high degree of alignment (e.g., S˜1) and packing (e.g., ˜10⁶ nanotubes in a cross-sectional area of 1 μm²) in a well-controlled, simple, and reproducible manner, regardless of the synthesis method, metallicity, or chirality of the carbon nanotubes used. Furthermore, the produced films are compatible with standard microfabrication processes to fabricate various electronic and photonic devices.

In some embodiments, the methods of the present disclosure allow one to have crystals of, for example, semiconducting (6,5), metallic (6,6), and quasi-metallic (7,4) carbon nanotubes, as illustrated in FIG. 5. Because such carbon nanotubes have distinctly different band structures (and, thus, distinctly different optical absorption properties), they have distinctly different colors.

### Additional Embodiments

Reference will now be made to more specific embodiments of the present disclosure and experimental results that provide support for such embodiments. However, the disclosure below is for illustrative purposes only and is not intended to limit the scope of the claimed subject matter in any way. The following examples are included to demonstrate particular aspects of the present disclosure. It should be appreciated by those of ordinary skill in the art that the methods described in the examples that follow merely represent illustrative embodiments of the disclosure. Those of ordinary skill in the art should, in light of the present disclosure, appreciate that many changes can be made in the specific embodiments described and still obtain a like or similar result without departing from the spirit and scope of the present disclosure.

### Example 1. Wafer-Scale Monodomain Films of Spontaneously-Aligned Single-Wall Carbon Nanotubes

In this Example, a simple and robust method is reported for preparing exceptionally large (>cm²) monodomain films of aligned SWCNTs based on spontaneous alignment that occurs during slow vacuum filtration. The produced films are globally aligned within ±1.5° (the nematic order parameter ˜1) and are highly packed, containing ˜10⁶ nanotubes in a cross-sectional area of 1 μm². The film thickness is controllable from 1 nm to ˜100 nm. Sufficiently thick films act as ideal polarizers in the terahertz frequency range. This method is universally applicable to SWCNTs synthesized by various methods. Moreover, by combining this method with recently-developed sorting techniques, highly-aligned and chirality-enriched SWCNT thin-film devices were fabricated. Semiconductor-enriched devices exhibited polarized light emission, polarization-dependent photocurrent, and anisotropic conductivities and transistor action with high on/off ratios. These results significantly advance the frontier of research toward scalable carbon-based electronics and photonics.

The process starts with preparation of a well-dispersed CNT suspension. A CNT powder with surfactant was dispersed in water to create an aqueous CNT suspension using tip sonication and ultra-centrifugation (See Example 1.1).

The second step utilizes vacuum filtration method (FIGS. 1a-b), which is a well-established technique for forming wafer-scale films of randomly-oriented CNTs with a controllable thickness. The CNT suspension prepared in the first step is poured into the filtration funnel with a small-pore-size filter membrane, and a differential pressure across the filter membrane pushes the suspension slowly through the pores, leaving CNTs on the filter membrane.

To obtain spontaneous CNT alignment in this nonlimiting example, one has to satisfy three conditions: i) the surfactant concentration may be below the critical micelle concentration (CMC); ii) the CNT concentration may be below a threshold value, and/or iii) the filtration process may be well controlled at a low speed. When these conditions are met, a wafer-scale, uniform, and aligned CNT film is formed on the filter membrane (FIG. 1b).

The film can then be transferred to any substrate in a straightforward manner after dissolving the filter membrane in a proper solvent (see Example 1.3). The result is a large-area, semi-transparent film of aligned CNTs, as shown in the optical (FIG. 1c), scanning electron microscopy (FIGS. 1d-e), and transmission electron microscopy (TEM) images (FIG. 1f).

As the cross-sectional TEM image in FIG. 1g shows, the film is densely packed, with ˜10⁶ CNTs found in a cross-sectional area of 1 μm². Individual CNTs within the film are all aligned with each other, forming a globally ordered structure with an angle standard deviation of ˜1.5° across the entire film (FIG. 1h). The film is optically polarized, i.e., linearly dichroic (FIGS. 1i-j), being opaque to light polarized parallel to the CNT alignment direction and transparent to light polarized perpendicular to the alignment direction.

Using cross-polarized microscopy, strong optical anisotropy can be demonstrated both on a macroscopic (cm) scale (FIG. 1i) and a microscopic (μm) scale (FIG. 1j), reflecting the global and local CNT alignment, respectively. Finally, the film can be easily patterned using conventional photolithography techniques (FIG. 1j).

FIGS. 2a-f summarizes results of spectroscopic characterization measurements of aligned CNT films. FIG. 2a shows polarized Raman spectra for a 15-nm-thick aligned film of arc-discharge SWCNTs with an average tube diameter of 1.4 nm, taken with an excitation wavelength of 514 nm in two polarization configurations. In the VV (HH) configuration, both the incident and scattered beams are polarized parallel (perpendicular) to the nanotube alignment direction. FIG. 2b provides polarization-dependent attenuation spectra in a wide spectral range, from the THz/far-infrared to the visible. The data was analyzed using standard equations for the angular dependence of SWCNT Raman spectra to deduce the value of S, which was 0.96 for this particular film. Electromagnetic response of this film was strongly polarization dependent in the whole spectral range, from the terahertz (THz) to the visible, as shown in FIG. 2b with the energy axis on a logarithmic scale. In particular, there is no detectable attenuation within experimental errors for the perpendicular polarization in the entire THz/infrared range (<1 eV) whereas there is a prominent, broad peak at ˜0.02 eV in the parallel case due to the plasmon resonance. FIG. 2c provides an expanded view of FIG. 2b, or more particularly, plots the same spectra with the energy axis on a linear scale, to more clearly show interband absorption—i.e., the first two interband transitions for semiconducting nanotubes (E₁₁^{S} and E₂₂^{S}) and the first interband transition in metallic nanotubes (E₁₁^{M}).

Due to the exceptionally high degree of CNT alignment, these peaks are completely absent for the perpendicular polarization, and instead, a broad absorption feature is observed in an intermediate energy region between the (E₁₁^{S} and E₂₂^{S}) peaks. Without being bound by theory, this feature appears to be attributed to the cross-polarized and depolarization-suppressed absorption peak, predicted more than 20 years ago and detected in polarized photoluminescence excitation spectroscopy experiments in individualized CNTs. This is the first time that this transition has been directly observed in standard absorption spectroscopy because of macroscopic alignment.

As noted previously, the exceptionally strong polarization-dependence of THz transmission through aligned CNT films can be utilized to form an ideal THz polarizer with extremely large extinction ratios (ER). ER=T_{|}/T_{⊥}, where T_{|} (T_{⊥}) is the transmittance for the parallel (perpendicular) polarization. FIG. 2d shows time-domain waveforms of THz radiation transmitted through an aligned arc-discharge SWCNT film on an intrinsic silicon substrate for polarizations parallel and perpendicular to the alignment direction, together with a reference waveform obtained for the substrate alone. The data for the perpendicular case completely overlaps with the reference trace (i.e., no attenuation is detectable). The THz beam had a beam size of mm², thus probing a macroscopic area.

The data for the perpendicular case completely coincides with the reference trace (i.e., no attenuation occurs within the SWCNT film). On the other hand, there is significant attenuation for the parallel case. Note that the THz beam had a mm² size, thus probing a macroscopic area. FIG. 2e shows a more detailed polarization-angle dependence of THz attenuation, plotted as a function of the angle between the THz polarization and the nanotube alignment direction. The attenuation anisotropy allows us to calculate the value of S in a straightforward manner, which also agrees with the value obtained by Raman spectroscopy. FIG. 2f shows the nematic order parameter (S), left axis, deduced from the THz attenuation data, and the extinction ratio (ER), right axis, as a function of film thickness. The value of ER monotonically increases with the film thickness, as expected, while high values of S are maintained even for relatively thick films (FIG. 2f).

Due to the ultrahigh density of the films, the ER per thickness calculated from FIG. 2f is unprecedentedly high, i.e., ˜12 dB/100 nm. Furthermore, the spectral range where the film effectively works as a polarizer, from ˜0.2 to ˜120 THz, is the widest ever reported for a CNT polarizer.

The methods of making aligned films is universally applicable to different types of SWCNTs. Table 1 lists seven representative suspensions used, which contained SWCNTs synthesized by the arc-discharge, CVD, CoMoCAT, and HiPco methods.

TABLE 1
Summary of different types of CNT suspensions used for
making aligned films.

| | | | dₜ | lₜ | | |
|---|---|---|---|---|---|---|
| Suspension | Synthesis | Surfactant | (nm) | (nm) | S_{THz} | S_{Raman} |
| #1 | Arc-Discharge | DOC | 1.4 | 227 | ~1 | 0.96 |
| #2 | Arc-Discharge | SDBS | 1.4 | 246 | ~1 | 0.94 |
| #3 | Arc-Discharge | N/A^{†} | 1.4 | 295 | 0.77 | 0.72 |
| #4 | CVD^{‡} | DOC | 1.8 | 307 | 0.9 | 0.85 |
| #5 | CoMoCAT | DOC | ~1 | 166 | N/A^{⊥} | 0.73 |
| #6 | CoMoCAT* | DOC | 0.73 | 420 | N/A^{⊥} | 0.75 |
| #7 | HiPco^{⊥} | DOC | ~0.9 | 298 | N/A^{⊥} | 0.72 |

dₜ: average tube diameter,
lₜ: average tube length,
S_{THz} (S_{Raman}): nematic order parameter obtained from THz (Raman) measurements,
DOC: sodium deoxycholate, and
SDBS: sodium dodecylbenzenesulfonate.
^{†}Suspension #3 contained arc-discharge-synthesized CNTs that were functionalized by polyaminobenzene sulfonic (PABS) acid.
^{‡}Suspension #4 contained TUBALL ™ nanotubes from OCSiAl (http://ocsial.com/en/product/tuball/).
*Suspension #6 was enriched in (6,5) SWCNTs.
^{τ}Suspension #7 was enriched in (7,6), (8,6), and (10,5) SWCNTs.
^{⊥}Suspension #5, #6, and #7 did not have high enough carrier densities to show strong enough THz attenuation to determine S_{THz}.

In Table 1, dₜ is the average nanotube diameter, and lₜ is the average nanotube length measured by atomic force microscopy. For dispersing CNTs, sodium deoxycholate (DOC) was used for Suspensions #1 and #4-#7 and sodium dodecylbenzenesulfonate (SDBS) for #2, as surfactant. Pre-functionalized, water-soluble SWCNTs were used in Suspension #3.

Successful formation of aligned films made from suspension #3 indicates that surfactant is not a crucial element for spontaneous CNT alignment, as long as the CNTs are well dispersed in the suspension. However, CNTs in all these suspensions were negatively charged. Thus, it is currently not clear whether CNT alignment can be achieved with positively charged or neutral surfactants.

Also listed in Table 1 are nematic order parameters, S_{THz} and S_{Raman}, as determined through THz and Raman measurements, respectively. Only S_{Raman} is shown for Suspensions #5, #6, and #7 because the films from these suspensions did not have sufficiently high carrier densities to show strong enough THz attenuation for determining S_{THz}. There is no apparent relationship observed between the structure parameters of SWCNTs and the achieved values of S_{THz} and S_{Raman}. Arc-discharge SWCNTs tend to align more strongly than other types of nanotubes, but further systematic studies using diameter- and length-sorted samples are needed to clarify whether this difference comes from their differences in dₜ, lₜ, or dₜ/lₜ.

The strikingly high values of S achieved precludes the possibility that the alignment mechanism is based on three-dimensional (3D) nematic ordering of rigid rods, for which Onsager's theory predicts an upper limit of S=0.79. Formation of a 3D nematic liquid-crystal phase of CNTs would require a high CNT concentration⁸, with a threshold value of ˜5 mg/mL for CNTs with lₜ/dₜ˜10³. This condition was not met in this case (typical CNT concentration ˜15 μg/mL, and lₜ/dₜ=150-550), suggesting that a different alignment mechanism is at work.

A clue for the mechanism comes from observations that the degree of alignment was sensitive to the hydrophobicity of the filter membrane surface, similar to a prior report on 2D nematic ordering of DNA-wrapped CNTs. Alignment was achieved only when the filter membrane had a hydrophilic coating layer (PVP). Additionally, control of the flow rate, CNT concentration, and surfactant concentration was crucial.

Based on these observations, and without being bound by theory, it is proposed that CNT alignment occurs in a 2D manner. Hydrophilic PVP coating makes the filter paper surface negatively charged during filtration, and as a result, negatively charged CNTs in the suspension are repelled from the surface. At the same time, CNTs feel van der Waals attraction from uncoated regions of the membrane surface. The competition of these two forces creates a potential minimum near the surface, where CNTs accumulate, interact with each other, and form an ordered 2D phase. Because the formation of ordered structure requires horizontal (i.e., in-plane) rotation of CNTs in a finite time period to arrange themselves within the 2D layer, an appropriate filtration speed and CNT concentration are important. Furthermore, the surfactant concentration affects the charge density on the PVP layer, which in turn influences the electrostatic repulsion potential, while at the same time the suspension viscosity depends on the surfactant concentration, which influences the rotational motion of CNTs in the 2D layer.

2D surface confinement is a novel route towards fabricating ordered nanostructures. In the Langmuir-Schaefer method for example, nano-objects initially float on the surface of water (i.e., confined at the interface between air and water), and eventually form an ordered phase. However, CNT concentrations used in previous studies were extremely low (e.g., 0.1-1 μg/mL). The obtained films of aligned CNTs remained small and thin (limited to a monolayer or several layers), and the degree of alignment was low (e.g., the Raman G-peak intensity anisotropy ≈10, compared to ˜160).

In addition to stronger alignment, the films have other distinct advantages. First, unlike the previous 2D ordering studies, the method allows continued accumulation of aligned CNTs to achieve optically thin films (˜100 nm). The fact that S values higher than the rigid-rod limit to such thicknesses suggests that some attractive interaction is present between the tubes when the surfactant concentration is low. Second, the cross-sectional areal density is as high as 10⁶ nanotubes/μm², orders of magnitude larger than any previous reports.

These two advantages indicate that a transition from 2D-like to 3D-like ordering occurs as CNTs gradually accumulate on the surface. Once there is an aligned layer, the CNTs that follow tend to align with the already-existing alignment direction. Finally, there is in principle no limitation on the achievable area of aligned films. Practically, it is only limited by the size of the filter membrane.

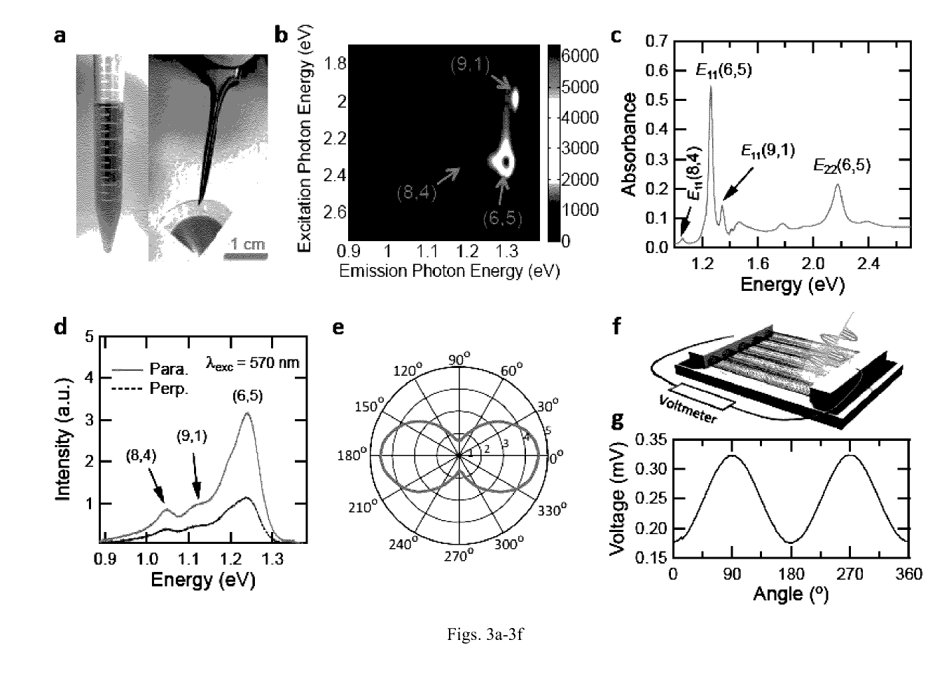

With the ultimate aim of developing optoelectronic technologies based on aligned single-chirality SWCNTs, CNT suspensions enriched in specific types and chiralities were used in making aligned CNT films (e.g., Suspension #6 in Table 1) and fabricated light emission and detection devices (FIGS. 3a-g).

Recent advances in post-growth separation and sorting techniques allow suspensions of specific chirality, (n,m), and SWCNTs at large enough quantities to be prepared for making macroscopic films. Here, the aqueous two-phase extraction method may be used to enrich (6,5) SWCNTs. FIG. 3a shows photographs of the prepared suspension and film while FIGS. 3b-c show the photoluminescence excitation spectra and optical absorption of the enriched suspension. There are trace amounts of (8,4) and (9,1) SWCNTs in the suspension, but it is clear that the majority of the nanotubes are (6,5) species. FIG. 3d shows strongly-polarized photoluminescence spectra for an aligned and (6,5)-enriched CNT film, showing stronger emission polarized parallel to the CNT alignment direction. FIG. 3e shows a polar plot of the intensity of the emitted photoluminescence from the aligned and (6,5)-enriched CNT film. This macroscopic manifestation of light emission anisotropy not only provides evidence that the CNTs in the film are highly aligned but also proves that there are no residual metallic tubes, which are known to be efficient photoluminescence quenchers when in contact with semiconducting nanotubes. This result opens up new possibilities of developing CNT-based light sources for producing polarized monochromatic radiation.

FIG. 3f shows a schematic diagram showing the photodetector device fabricated from an aligned and (6,5)-enriched CNT film. FIG. 3g shows polarization-dependent photovoltage observed for the device shown in FIG. 3f. The photodetector was a two-terminal device (see Example 1.4 and FIG. 3f), which exhibited strongly polarization-sensitive photosignal (FIG. 3g). The polarization ratio of photosignal magnitude was ˜2:1. The responsivity of the photodetector was estimated to be ˜0.1 V/W, after taking into account the actual power absorption of ˜3.1 mW when the light polarization is parallel to the CNT alignment direction. Compared to previous photodetectors with the same device architecture but consisting of a mixture of metallic and semiconducting SWCNTs, the responsivity of the current photodectector has been enhanced by at least three times, most likely due to the removal of metallic tubes. It should be noted, however, that the current device design has not been fully optimized. With proper thermal management through selection and adjustment of substrates and other critical elements, the detector performance can be further improved³⁴.

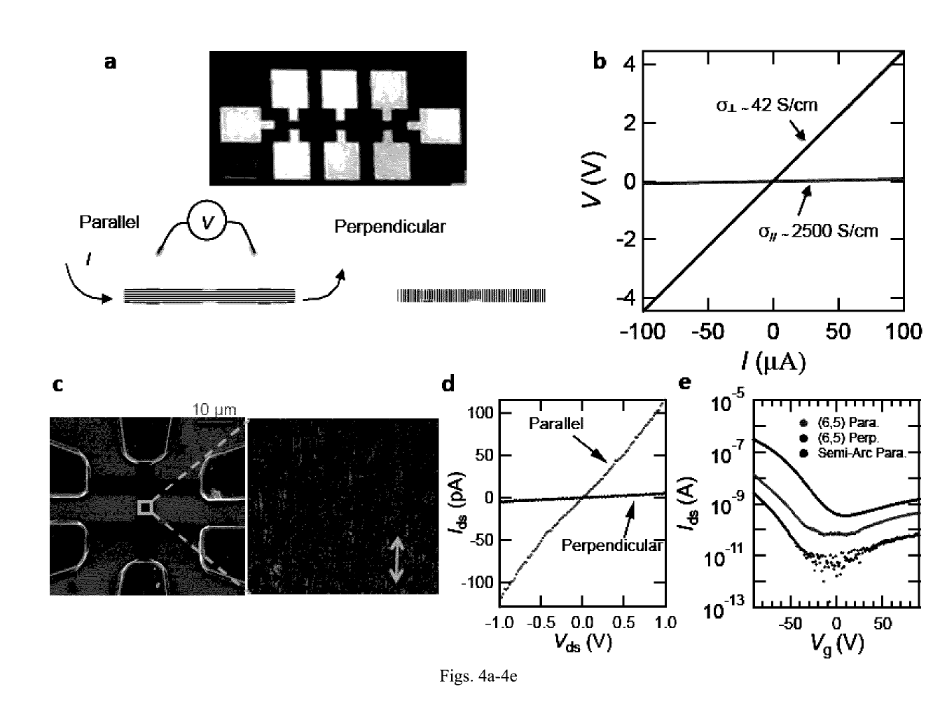

Finally, the electronic devices were fabricated out of aligned CNT films using standard microfabrication techniques and tested their conductivities and transistor performance (FIGS. 4a-e). FIG. 4a shows a photograph and a schematic diagram of Hall-bar devices with a channel length of ˜5 mm and a channel width of ˜0.5 mm used to characterize the macroscopic anisotropic transport of charge carriers in an aligned film comprising unsorted arc-discharge CNTs via four-terminal measurements. FIG. 4b shows voltage-current relationship of the Hall-bar devices when the current flow is parallel and perpendicular to the CNT alignment direction, showing anisotropic conductivities. First, strong conductivity anisotropy were observed in Hall-bar devices made of aligned unsorted arc-discharge CNTs at room temperature (FIGS. 4a-b). The ratio of conductivity between the parallel and perpendicular directions is as high as 60 (FIG. 4b).

The conductivity along the alignment direction was 2500 S/cm. In conventional, randomly-aligned CNT films made by vacuum filtration, conductivity values as high as this value are obtainable only with heavy doping while the improved films are not intentionally doped. In addition, transistor behaviors of a (6,5)-enriched aligned film (FIG. 4c) was investigated. FIG. 4c shows false-color scanning electron microscopy images of a thin-film transistor with channel width of ˜5 μm and a channel length of ˜30 μm made from an aligned and (6,5)-enriched CNT film. FIG. 4f shows the source-drain current versus source-drain voltage at zero gate voltage of the transistor showing anisotropic conductivities of the aligned (6,5)-enriched thin-film transistor. FIG. 4e shows the source-drain current at a source-drain voltage of 1 V versus gate voltage of the (6,5)-enriched transistor showing large and anisotropic transistor action. The on-current density is enhanced by 50 times in a transistor made from larger-diameter semiconductor-enriched arc-discharge SWCNTs. As shown in FIGS. 4d-e, the on-current density of the transistor in the parallel (perpendicular) direction is ˜2 nA/μm (˜80 pA/μm), indicating that the on-current density can be improved through aligning CNTs in one direction. Note that these intrinsic semiconducting films are naturally much less conducting that purely metallic films or films with mixed electronic types.

As shown previously, the on-current density can also be enhanced by using larger-diameter nanotubes, which is also demonstrated by the transistor based on semiconductor-enriched arc-discharge CNTs with an average diameter of 1.4 nm (FIG. 4e). The device shows an enhancement of on-current density by ˜50 times compared to the (6,5) CNT transistor at the same drain-source voltage. The on-off ratios of the transistors are around 10³, which is comparable to previous results for transistors made of aligned CNT films. Without being bound by theory, the relatively low on-off ratio is ascribed to the charge screening effect caused by the high packing of CNTs in one direction. It can be overcome by using a high-κ dielectric material or using a top-gate architecture.

In summary, a new process to produce a wafer-scale (i.e., inch-size) film of aligned CNTs of an adjustable thickness is reported. This method works for CNTs synthesized by various methods and is expected to be applicable to other high aspect-ratio, rod-like nanostructures that can be suspended in the same way as used in the experiments. Terahertz/infrared polarizers have been demonstrated using metal-semiconductor mixed CNTs, thin-film transistors using semiconducting CNTs, polarized light emission devices using semiconducting CNTs, and polarization-sensitive CNT detectors.

### Example 1.1. CNT Suspension Preparation

Two batches of arc-discharge SWCNTs (P2-SWNT and P8-SWNT) with an average diameter of 1.4 nm were purchased from Carbon Solutions, Inc. Two types of Co-MoCAT SWCNTs (CG 200 and SG 65i) were purchased from Sigma-Aldrich. The former had a wide diameter distribution (0.7-1.4 nm), whereas the latter was enriched in (6,5) SWCNTs with ˜90% purity. CVD-grown TUBALL™ CNTs, which were 75% SWCNTs, were obtained from OCSiAl and had an average diameter of ˜1.8 nm. HiPco SWCNTs (batch #195.5), with a diameter range of 0.9-1 nm, were used after purification and diameter sorting.

As surfactants for CNT dispersion, sodium deoxycholate (DOC, Sigma-Aldrich) and sodium dodecylbenzenesulfonate (SDBS, Sigma-Aldrich) were used. All CNTs (except for P8-SWNT) were initially dispersed in either 1% (wt./vol.) DOC or 0.4% (wt./vol) SDBS by bath sonication (Cole-Parmer 60-W ultrasonic cleaner, model #08849-00) for 5-10 minutes at a starting concentration of 0.2-0.8 mg/mL. The obtained suspension was then further sonicated with a tip sonicator (XL-2000 Sonicator, Qsonica, LLC., ¼″ probe, ˜30 watts) for 45-60 minutes. The suspension was cooled in an ice water bath during the sonication. Next, the suspension was centrifuged for 1 hour at 38000 rμm (Sorvall Discovery 100SE Ultracentrifuge using a Beckman SW-41 Ti swing bucket rotor) to remove large bundles of CNTs. After centrifugation, the upper 60% of the supernatant was collected and then diluted with Nanopure water. The concentration of surfactant was diluted below its critical micelle concentration (CMC). Depending on the type of CNTs used, the final concentration of DOC before film making varied from 0.02% to 0.1%, and the final concentration of SDBS was ˜0.02%.

### Example 1.2. Vacuum Filtration

Well-dispersed CNT suspensions with dilute CNTs (˜1-15 μg/mL) and dilute surfactant (below CMC) was filtered through a vacuum filtration system in a well-controlled manner. Polycarbonate filter membranes (Nuclepore Track-Etched Polycarbonate Hydrophilic Membranes) with different pore sizes from 50 to 200 nm were used. The filtration speed was kept low and controlled in a range of 1-2 mL/hour. The pressure applied to the system by vacuum pumping was monitored through sensitive pressure gauges. A speeding-up procedure was performed at the end of the filtration process to dry the film quickly. For this fast-dry procedure, the filtration speed was increased from ˜1 mL/hour to ˜10 mL/hour. Before transferring the film onto another substrate, the film was pumped on for an additional 15-30 minutes.

### Example 1.3. Transfer and Characterization

For characterization and device fabrication, films were transferred onto solid substrates (e.g., SiO₂/Si and quartz) using a wet transfer process, in which the polycarbonate filter membrane was dissolved away with organic solvent (N-methyl-2-pyrrolidone or chloroform). The films were then thoroughly washed by acetone and nanopure water. Subsequent X-ray photoelectron spectroscopy experiments did not detect any residual surfactants. Properties of fabricated CNT films were characterized by various methods. Anisotropic optical transmission on a large scale was characterized by polarized optical microscopy in both co-polarized and cross-polarized configurations. Alignment structure on micro- and nano-meter scales was examined by scanning electron microscopy (JEOL 6500F Scanning Electron Microscope) and transmission electron microscopy (JEOL 2100 Field Emission Gun Transmission Electron Microscope). The quality of CNT alignment was characterized in terms of local and global nematic order parameters based on polarized Raman spectroscopy (RENISHAW inVia Raman Microscope) and terahertz transmission spectroscopy (a home-made time-domain THz spectroscopy system). Film thicknesses were measured by atomic force microscopy (Bruker Multimode 8). The average lengths of CNTs in suspensions were measured by atomic force microscopy. Photoluminescence excitation spectra of the single-chirality (6,5) CNT suspension and polarized photoluminescence of the single-chirality (6,5) films were measured with a home-made photoluminescence excitation spectroscopy setup.

### Example 1.4. Photodetector Fabrication

Aligned (6,5) nanotube films were cut into ribbons and then transferred to glass substrates. Two electrodes were formed by sputtering 50-nm gold with a shadow mask at the two ends of a ribbon. A 660-nm laser beam with a maximum power of ˜50 mW was incident on and near a gold-CNT junction. A half-wave plate was used to rotate the polarization of the incident light beam without changing the incident power. The generated photo-voltage was amplified by a Stanford Research SR560 voltage preamplifier and then fed into a Stanford Research SR830 lock-in amplifier.

### Example 1.5. Hall-Bar Device and Field Effect Transistor Fabrication

An aligned nanotube film was transferred onto a substrate comprised of heavily doped silicon (acting as a global back gate for the field effect transistors) and 285-nm thick layer of thermal silicon oxide (acting as the insulating layer). The first photolithography step was to define the electrode area with Shipley Microposit S1813 photoresist. The electrodes were defined and fabricated by lifting off electron-beam-evaporated titanium (1 nm)/palladium (10 nm)/gold (20 nm). The next step was to define a Hall bar structure with one channel parallel and the others perpendicular to the CNT alignment direction, as shown in FIGS. 4A-C. Anisotropic transport measurements of the aligned film comprising unsorted arc-discharge CNTs were performed under ambient conditions via four-terminal sensing using a Keithley 2400 source meter. Field effect transistor measurements were performed under vacuum (˜1×10⁻⁵ torr), using a Keithley 2634B source meter (for the source-drain voltage) and a Keithley 2400 source meter (for the gate voltage).

### Example 2

### Preparation of CNT Suspensions

For the CoMoCAT SG-65i sample, after dispersion and centrifugation (see Methods), the aqueous two-phase extraction (ATPE) method was adopted to perform chirality separation. After chirality separation, the dextran and polyethylene glycol (PEG) used in the ATPE method were removed by ultrafiltration. The concentration of surfactant was then readjusted to the value required for making films.

Arc-discharge P8-SWNTs are water-soluble because of functionalization by mpolyaminobenzene sulfonic (PABS) acid. The CNT powder was directly dissolved into nanopure water with an initial concentration of ˜0.5 mg/mL. In order to get better dispersion, the suspension was tip-sonicated for 45 minutes and then centrifuged, as described in the Methods section; the upper ˜60% of the supernatant was collected for making films.

HiPco single-wall carbon nanotubes (SWCNTs), batch #195.5, were dispersed by DOC (1% wt./vol.) with an initial concentration of ˜0.6 mg/mL of SWCNTs. After centrifugation, the supernatant (˜0.3 mg/mL) was collected and further purified and sorted by the ATPE method. The purified sample was enriched in the chiralities (10,5), (8,6), and (7,6), with an average diameter was 0.9-1 nm.

Fabrication of Aligned CNT Films: Filtration System

The experimental system comprises a filtration setup (filter membranes, filtration funnel, etc.), a vacuum pump, and multiple pressure gauges. The vacuum pumping rate was controlled by valves, and the applied pressure was monitored by pressure gauges mounted on the vacuum line.

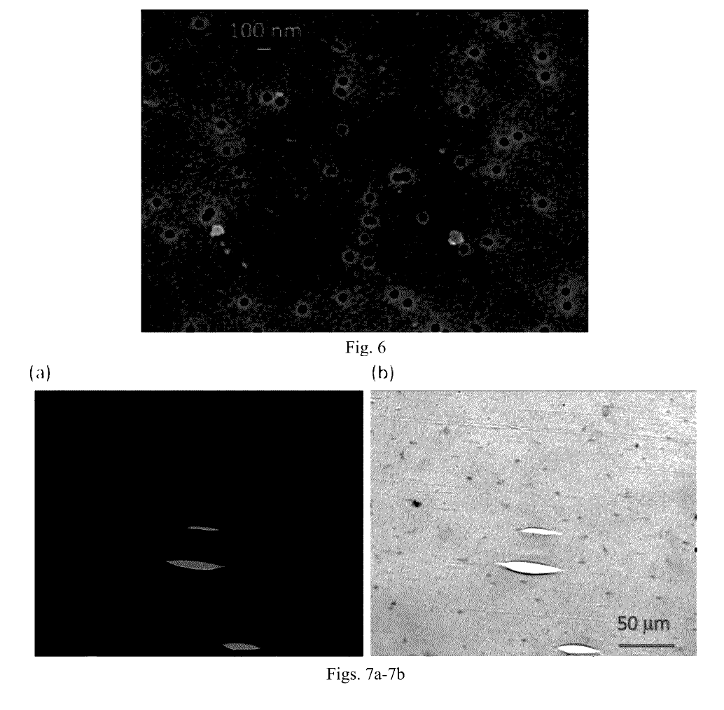

The Nuclepore track-etched polycarbonate (hydrophilic) filter membranes used were purchased from GE Healthcare Life Sciences. The pore sizes included 80 nm, 100 nm, and 200 nm. FIG. 6 shows a SEM image of the polycarbonate filter membrane with 100 nm pore size.

The filtration setup (Millipore® XX1002500 glass microanalysis 25 mm vacuum filter holder with 15 mL funnel and fritted glass filter support) was purchased from Fisher Scientific Company, LLC, including a 15 mL glass funnel, a fritted glass filter support, and a silicone stopper for the attachment to a vacuum filtering flask. The vacuum pump (Fisher Scientific™ Maimadry™ Oil-Free Vacuum Pump) was purchased from Fisher Scientific Company, LLC. Pressure gauges (Magnehelic Differential Pressure Gauge) with different ranges were purchased from Dwyer Instruments, Inc.

Filtration Procedure

The filtration procedure generally included the following three steps for the purpose of controlling the filtration speed at a slow and steady rate.

Step I:

Put a gentle or zero pressure on the filtration system at the beginning so that the filtration speed of the CNT suspension is as slow as 1-2.5 mL/hour. This can be achieved by controlling multiple valves in the vacuum line to adjust the vacuum pumping rate and choosing filter membranes with different pore sizes.

Step II:

Monitor the filtration speed during the filtration process. As CNTs are gradually deposited on the filter membrane, the flow rate slows down. Try to keep the speed above 0.5 mL/hour in order to avoid inhomogeneous deposition of CNTs.

Step III:

Increase the filtration rate at the end of the filtration process. The CNT layer deposited on the filter membrane can be disturbed by the residual solution at the end of the filtration if the speed is slow (˜1-2.5 mL/hour). The increase in filtration rate at the end is important to achieve a uniform CNT layer and protect the alignment structures from being destroyed by the residual solution. Usually, the increase is begun when there is still a certain distance (˜3-5 millimeters) between the upper surface of the filtering suspension and the surface of the filter membrane. Before the two surfaces touch each other, a final steady speed is reached around 1 drop/20 seconds, namely ˜10 mL/hour.

Filtration Details of Different Types of CNTs

Arc-Discharge SWCNTs:

The original P2-SWNT concentration after tip sonication was 0.4 mg/mL. After centrifugation, a P2-SWNT suspension of ˜0.15 mg/mL in DOC (1% wt./vol.) or SDBS (0.4% wt./vol.) was obtained, which was then diluted by nanopure water. The concentration of CNTs after dilution was ˜15 μg/mL, and the DOC concentration was ˜0.1% for DOC-dispersed samples, while the SDBS concentration was ˜0.02% for SDBS-dispersed samples. For P8-SWNTs, the concentration of CNTs was ˜10 μg/mL in water. Polycarbonate filter membranes with a pore size of 200 nm were used for the filtration of arc-discharge CNT suspensions. No pressure was applied on the system at the beginning of filtration as the pore size of filter membranes was large enough to establish a desired filtration speed. The speeding up started when there was ˜15%-20% suspension left. The final speed was stabilized at around 20 seconds per drop. The time for the entire filtration of 4-5 mL sample was 1.5-2 hours. After the filtration was finished, the film was kept under pressure for an additional 15-30 minutes, allowing the film to dry completely.

TUBALL CNTs:

The original CNT concentration was 0.4 mg/mL, A CNT suspension of ˜0.14 mg/mL was obtained in DOC surfactant (1% wt./vol.) after centrifugation. After dilution with nanopure water, the concentration of CNTs and DOC surfactant were ˜14 μg/mL and 0.1% wt./vol., respectively. The filtration procedure was the same as for the arc-discharge CNTs described above.

CoMoCAT SWCNTs (CG200):

The original CNT suspension of ˜0.4 mg/mL was dispersed in DOC surfactant (1%). After centrifugation, the sample was diluted by either Nanopure water or DOC solution with a certain concentration, the final concentration of CNT and DOC surfactant for film making were in the range from 4 μg/mL-30 μg/mL and 0.03-0.5%, respectively. Polycarbonate filter membranes with a pore size of 80 nm were used for sample filtration. A weak pressure of 10-30 Pascal was applied to the system at the beginning, which was measured by pressure meters mounted in the vacuum pipeline. The filtration speed was around 5-6 minutes per drop in the beginning. The final speed was increased up to 20 seconds per drop in order to fix and dry the film fast. For a sample with ˜1 mL volume, it took around one hour to finish the entire filtration process.

CoMoCAT SWCNTs (SG65i):

The original CNT solution of ˜0.4 mg/mL was dispersed in DOC surfactant (1%). After type separation (ATPE) and sample cleaning via ultrafiltration, the concentration of CNTs was adjusted to ˜4 μg/mL determined by its optical density from UV-Vis-NIR absorption spectroscopy. The concentration of DOC surfactant was readjusted to 0.025%. Polycarbonate filter membrane with a pore size of 80 nm was used for filtration, and the procedure was the same as that for CoMoCAT CG200 described above.

HiPco SWCNTs (Batch #195.5):

After the purification and sorting, the sample was diluted by nanopure water, and the concentration of SWCNTs was readjusted to ˜12 μg/mL. The concentration of DOC surfactant was readjusted to 0.04%. Polycarbonate filter membrane with a pore size of 80 nm was used for the filtration, and the procedure was the same as that for CoMoCAT CG200 described above.

Characterization of Aligned CNT Films

Before characterization measurements, the CNT films were transferred to different solid substrates (silicon, SiO₂/Si, quartz, etc.) by a wet transfer technique, thoroughly cleaned by nanopure water, and dried by nitrogen gas. During the transfer process, the filter membrane was dissolved by N-methyl-2-pyrrolidone (NMP) or chloroform.

Polarized Optical Microscopy:

A Zeiss Axioplan 2 microscope was used to optically characterize the CNT film on a macroscopic scale. Two modes (cross-polarized and co-polarized) were used. For the former case, the polarizer and analyzer were placed orthogonally. When the CNT alignment direction was along the polarization direction of either the polarizer or analyzer, the film was opaque. When the CNT alignment direction was 45 degrees with respective to the polarization direction, the film was bright. The optical images for arc-discharge CNTs (P2-SWNT) under cross-polarized mode are shown in FIGS. 1g and 1h. As for the co-polarized mode, the polarizer and analyzer were put parallel. When the light polarization was parallel to the CNT alignment direction, the film was opaque; when the light polarization was perpendicular to the CNT alignment direction, the film was semi-transparent. Shown in FIG. 7a-b are optical images taken in the co-polarized mode for an aligned arc-discharge (P2-SWNT) CNT film on a quartz substrate. The left and right images show the same area in the same sample with the polarization direction of incident light parallel (FIG. 7a) and perpendicular (FIG. 7b) to the CNT alignment direction, respectively. The cracks of the film indicate the direction of CNT alignment. The transmittance of the whole film changed remarkably for the two light polarization directions due to the perfectly global alignment of the CNT film.

Scanning Electron Microscopy (SEM) and Transmission Electron Microscopy (TEM):

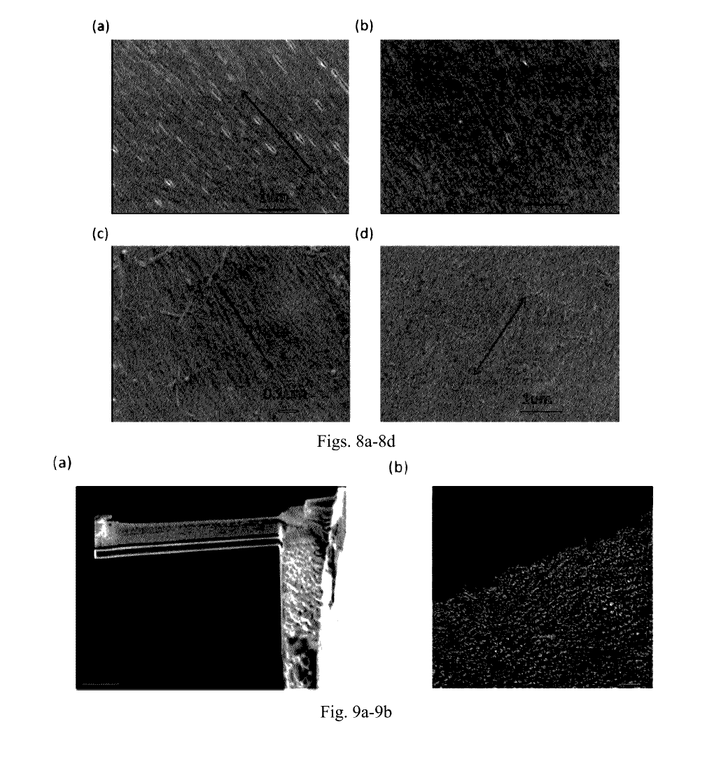

SEM and TEM were used to characterize the alignment of CNTs on a microscopic scale. The SEM images in FIG. 8a-d show the alignment structures of films made by different types of CNTs. More particularly, FIG. 8a-d shows (a) Arcdischarge (P2-SWNT) dispersed in SDBS surfactant. (b) Tuball CNTs dispersed in DOC surfactant. (c) Arc-discharge (P8-SWNT) dispersed in nanopure water. (d) CoMoCAT (CG200) dispersed in DOC surfactant. All SEM images were taken using a JEOL 6500F scanning electron microscope. Both TEM in-plane and cross-section images (FIGS. 9a-b) were taken using a JEOL 2100 field emission gun transmission electron microscope.

Preparation of a cross-sectional CNT sample was made as follows. An aligned arc-discharge SWCNT film was transferred onto a SiO₂/Si substrate and cut perpendicular to the overall alignment direction with a focused ion beam (FIB) using a FEI Helios 660 SEM/FIB. The slab thickness was reduced to ˜70 nm, as shown in FIG. 9a, to expose the circular cross-sections of nanotubes for HRTEM. The FIB sample was loaded onto a double-tilted stage to align the incident electron beam with the sample. FIG. 9bb shows a cross-sectional TEM image of an aligned carbon nanotube film with high magnification. The inability to clearly distinguish all the nanotube cross-section in FIG. 9b is highly likely due to slight misalignment between the nanotube axis and incident electron beam. The circular tube cross-section is very sensitive to the tilt angle. A small misalignment (˜0.1 degree) will make most of the circular tube cross-section appear out-of-focus since we are looking at the projection of the nanotube over ˜70 nm thickness. Other reasons may include the surface roughness and curvature of the nanotubes along the tube axis.

Polarized Raman Spectroscopy:

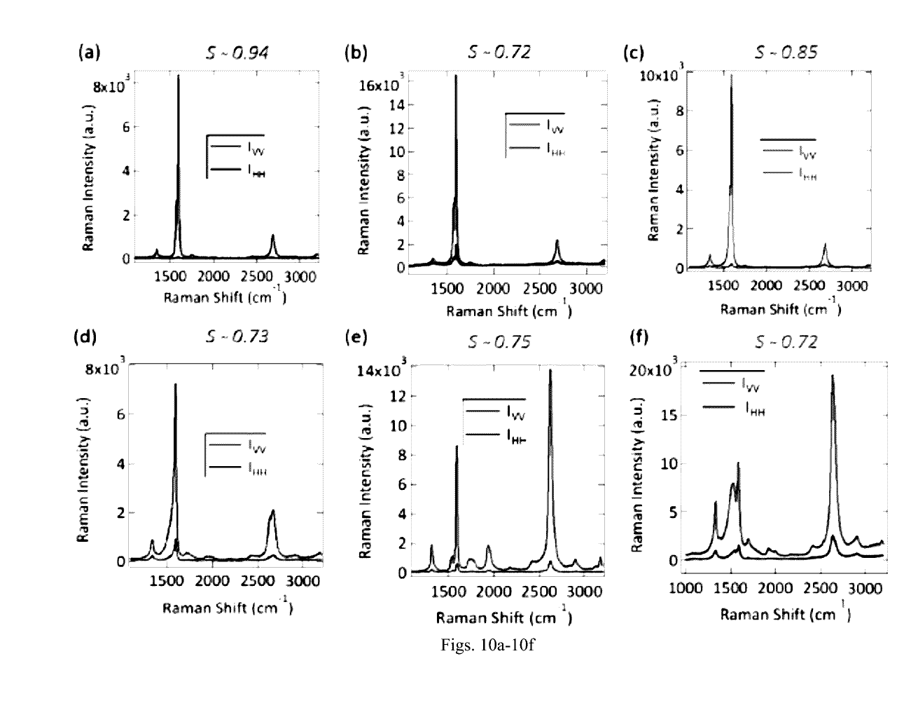

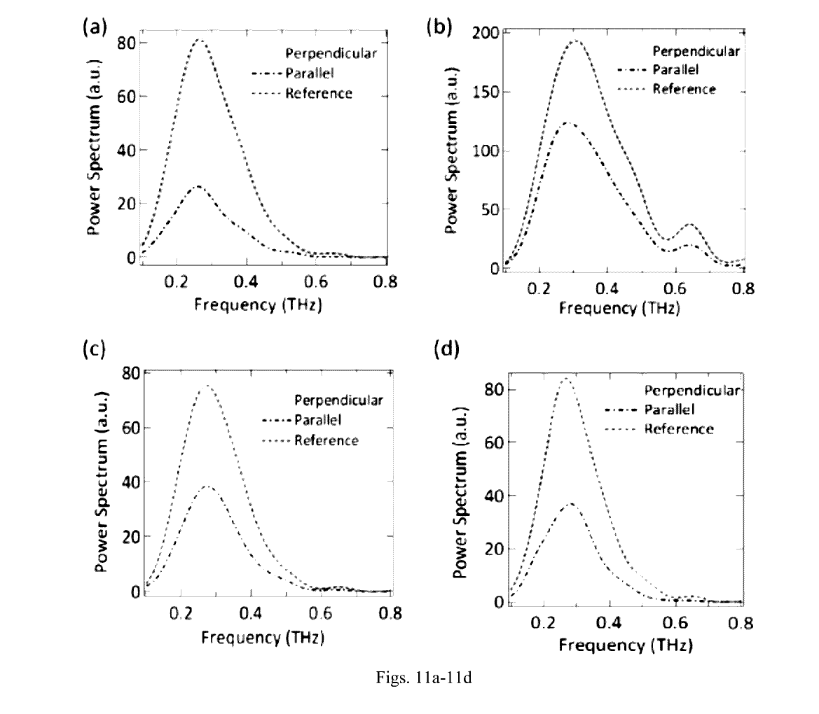

A Renishaw inVia Raman microscope was used to quantitatively characterize the degree of alignment of CNT films. The Raman spectra of aligned films made of other different types (Suspension #2-Suspension #7 in Table 1) besides arc-discharge (P2-SWNT) CNTs dispersed in DOC were also measured under different polarization configurations (I_{VV}, I_{VH}, and I_{HH}) with an excitation laser wavelength of 514 nm, as shown in FIGS. 10a-f. FIGS. 10a-f show polarized Raman Spectra of aligned films made from different types of CNTs, or more particularly (a) Arc-discharge SWCNTs (P2-SWNT) dispersed by SDBS surfactant; (b) PABS functionalized arc-discharge SWCNTs (P8-SWNT) dispersed in nanopure water; (c) TUBALL CNTs dispersed by DOC surfactant; (d) CoMoCAT CG200 CNTs dispersed in DOC; (e) (6,5)-chirality enriched sample separated from CoMoCAT SG65i CNTs dispersed in DOC; and (f) HiPco SWCNTs (batch #195.5) dispersed in DOC. The VV configuration is where the polarization of the incident and scattered beams are parallel to the CNT alignment direction; the VH configuration is where the incident polarization is parallel to the CNT alignment direction but is perpendicular to the scattering polarization, and the HH configuration is where the polarizations of the incident and scattered beams are perpendicular to the CNT alignment direction. The dichroic ratio, Δ, is defined as Δ=A_{∥}/A_{⊥}, where A_{∥} and A_{⊥} are the parallel and perpendicular absorbance at 514 nm, respectively. The nematic order parameter, S, was then calculated based on the polarized Raman spectra taken in three different polarization configurations and the dichroic ratio through the following equation:

$${S}_{Raman} = \frac{6 Δ {I}_{VV} + 3 ( 1 + Δ ) {I}_{VH} - 8 {I}_{HH}}{6 Δ {I}_{VV} + 12 ( 1 + Δ ) {I}_{VH} + 16 {I}_{HH}} \qquad ( 1 )$$

Terahertz (THz) Time-Domain Spectroscopy (THz-TDS):

THz-TDS was used to quantitatively characterize the degree of alignment on a macroscopic scale (˜1 mm²). The experimental setup was a transmission THz-TDS system using an ultrafast Ti:Sapphire laser. Already linearly-polarized THz radiation went through a wire-grid polarizer before being focused onto the sample. The CNT films were transferred onto intrinsic silicon substrates for the transmission measurements. The thickness of the films ranged from 10-100 nm, and their areas were on the order of cm² to fully cover the THz beam size ˜mm². Polarization-dependent THz transmission data were obtained by rotating the sample, changing the direction of CNT alignment with respect to the polarization direction of the incident beam. The polarization-dependent THz transmission frequency-domain spectra of aligned films (Suspension #1-Suspension #4 in Table 1) are shown in FIGS. 11a-d. FIGS. 11a-d show THz transmission spectra of aligned CNT films made by different types of CNTs, or more particularly (a) P2-SWNT dispersed in DOC surfactant; (b) P2-SWNT dispersed in SDBS surfactant; (c) TUBALL CNTs dispersed in DOC surfactant; and (d) P8-SWNT dispersed in nanopure water. The reduced linear dichroism (LD^{r}) and subsequent S were calculated based on the THz transmission data using the following equation:

$${S}_{THz} = \frac{{A}_{//} - {A}_{⊥}}{{A}_{//} + 2 {A}_{⊥}} \qquad ( 2 )$$

Atomic Force Microscopy (AFM):

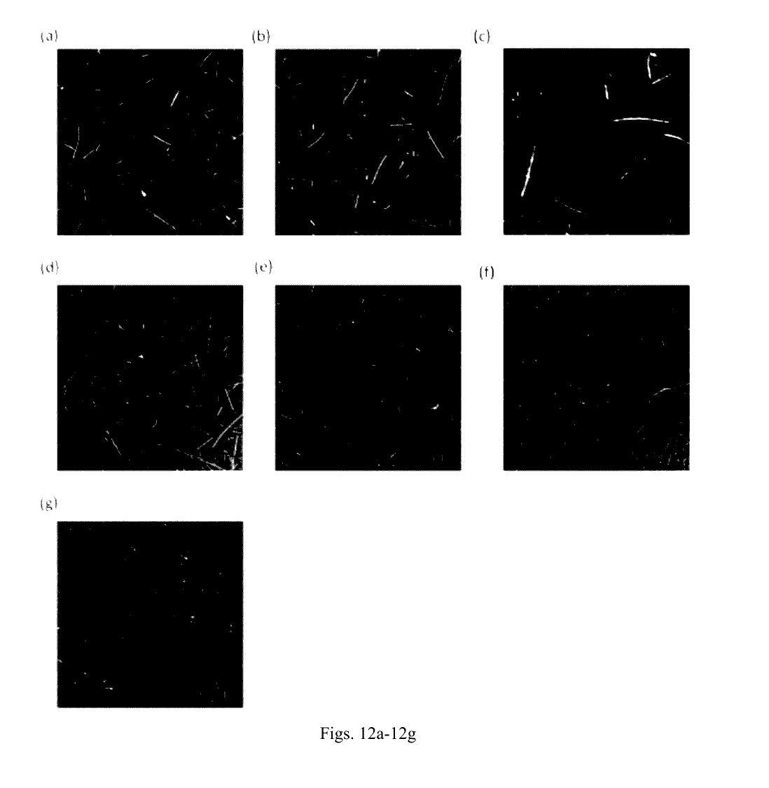

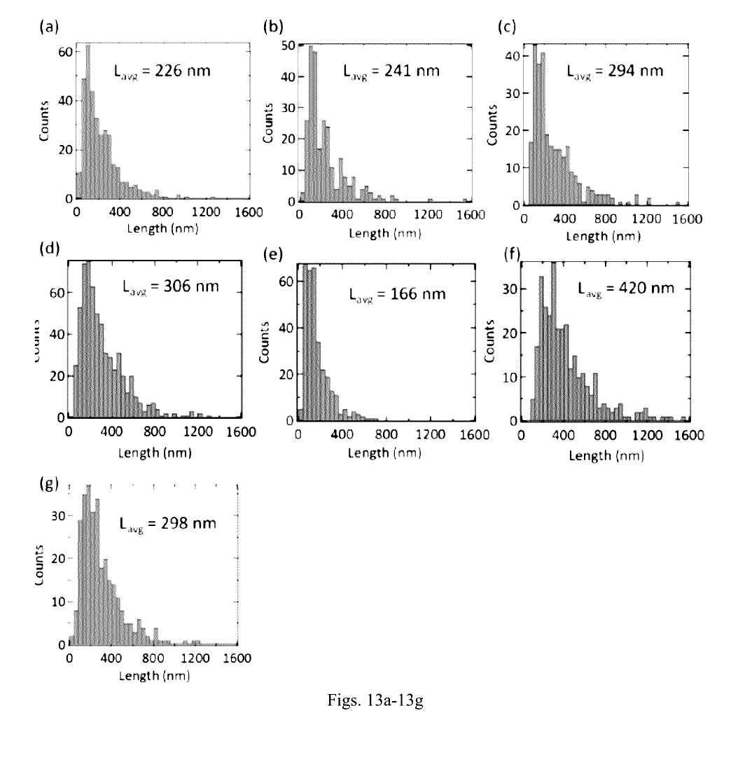

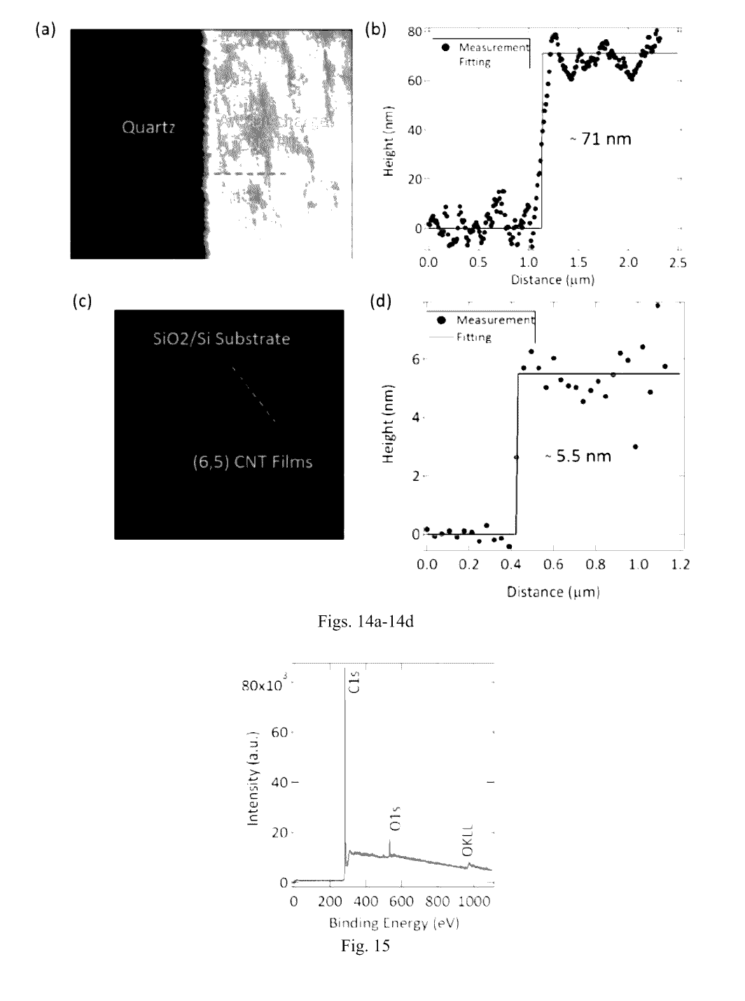

A Bruker Multimode 8 AFM was used to characterize the average length of CNTs and the thicknesses of the CNT films. FIGS. 12a-g shows AFM images of seven CNT samples used in this study, or more particularly (a) Arc-discharge P2-SWNT dispersed by DOC; (b) Arc-discharge P2-SWNT dispersed by SDBS; (c) Arcdischarge P8-SWNT dispersed by nanopure water; (d) Tuball CNTs dispersed by DOC; (e) CoMoCAT CG200 dispersed by DOC; (f) CoMoCAT SG65i dispersed by DOC; and (g) HiPco SWCNTs (batch #195.5) dispersed by DOC. The average length of CNTs (see FIGS. 13a-g) was statistically calculated based on the AFM images. FIGS. 13a-g show length distribution of seven CNT samples used in the work, or more particularly (a) Arc-discharge P2-SWNT dispersed by DOC; (b) Arc-discharge P2-SWNT dispersed by SDBS; (c) Arc-discharge P8-SWNT dispersed by DI water; (d) TUBALL CNTs dispersed by DOC; (e) CoMoCAT CG200 dispersed by DOC; (f) CoMoCAT SG65i dispersed by DOC; and (g) HiPco SWCNTs (batch #195.5) dispersed by DOC. FIGS. 14a-d show thickness characterization of CNT films, or more particularly (a) the AFM image of P2-SWNT film on quartz substrate; (b) corresponding height profile across the red dashed line in (a); (c) the AFM image of (6,5)-enriched thin film transistor on SiO2 substrate; and (d) corresponding height profile across the red dashed line in (c). FIGS. 14a and 14b show the typical thickness of an arc-discharge (P2-SWNT) CNT film to be ˜71 nm, and FIGS. 14c and 14d show the typical thickness of the (6,5) thin film transistor to be ˜5.5 nm. Note that the dashed lines in FIGS. 14a and 14c indicate the lines along which the height profiles in FIGS. 14b and 14d were measured.

Photoluminescence Excitation (PLE) Spectroscopy:

PLE was used to characterize the purity of the (6,5)-enriched sample. A homemade PLE setup had excitation and emission spectral ranges from 450 to 800 nm and from 850 to 1400 nm, respectively. The setup comprised a white light source (xenon lamp), a monochromator, a cold mirror, and an InGaAs CCD detector. The PL of (6,5)-enriched film was measured directly on the filter membrane after the filtration and drying procedures at fixed excitation wavelength 570 nm, on resonance with E₂₂ of (6,5)-enriched film, while the suspension sample was put in a quartz cuvette for the PLE measurements. Both PL and PLE data were taken in reflection geometry at room temperature. In order to check the polarization of PL from the aligned CNT film, a polarizer was inserted between the sample and the InGaAs detector.

X-Ray Photoelectron Spectroscopy (XPS):

Survey spectra of an aligned CNT thin film and a polycarbonate filter membrane were taken using an X-ray photoelectron spectrometer (PHI Quantera XPS). The monochromatic X-ray source was A1 Kα with an energy of 1486.7 eV, a beam spot size of 200 μm, and a power of 50 W. The pass energy was set to 140 eV. Shown in FIG. 15 is an XPS spectrum from an aligned CNT film with ˜50 nm thickness, transferred onto a SiO2/Si substrate after thoroughly washing by acetone and nanopure water. The absence of a sodium peak in the XPS spectrum indicates that the CNT film is clean, free of surfactants.

### Preparation and Characterization of Semiconductor-Enriched Arc-Discharge Samples

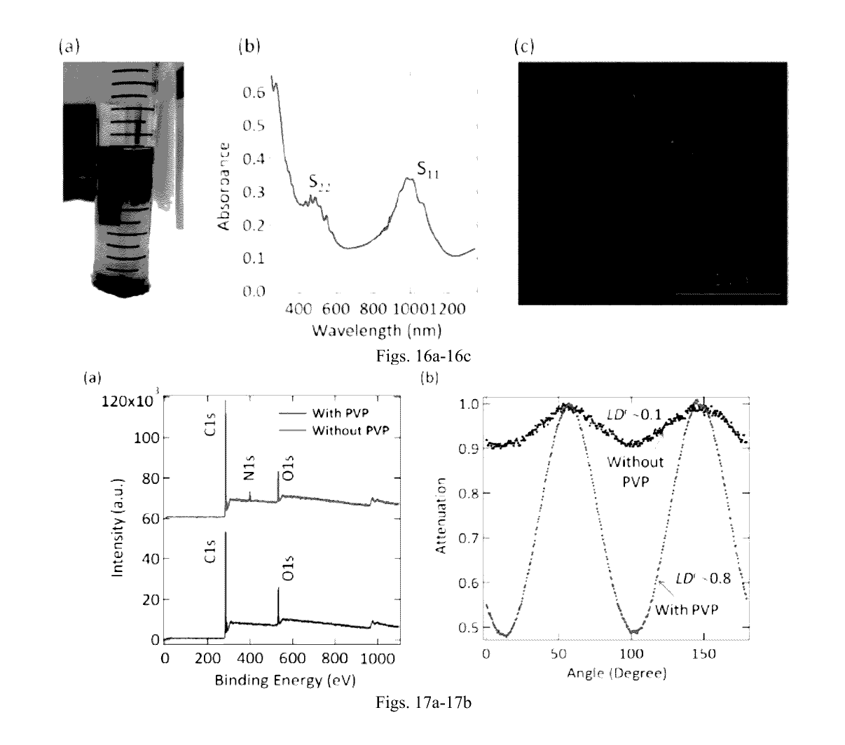

Semiconductor-metal separation was performed on arc-discharge (P2-SWNT) CNTs by redox sorting method (FIG. 16a). FIGS. 16a-c show (a) photograph and (b) optical absorption spectrum of a semiconductor-enriched CNT suspension separated from arc-discharge P2-SWNT, and (c) SEM image of an aligned film made from semiconductor-enriched P2-SWNT. The red arrow shows the direction of CNT alignment.

Factors Affecting the Degree of CNT Alignment

There are several important factors that have a strong influence on the degree of alignment for all types of CNTs. These factors include, but are not limited to, the filter membrane surface properties, the concentration of surfactant, the concentration of CNTs, and/or the filtration speed. The polarization-dependent absorption spectra of the fabricated CNT films were measured using a 660 nm diode laser. The LD^{r} defined as LD^{r}=3(A_{∥}−A_{⊥})/(A_{∥}+2A_{⊥}) at this wavelength was then calculated and used as a measure of the degree of alignment, together with SEM images, to evaluate the alignment quality under different conditions.

Filter Membrane Surface Properties

For this study, two types of polycarbonate filter membranes were used. Type A is coated with a layer of poly (vinylpyrrolidone) (PVP) on the surface and therefore is hydrophilic, Type B is hydrophobic without PVP coating on the surface. The presence of PVP coating can be detected by nitrogen is peak in X-ray photoelectron spectroscopy (XPS). FIGS. 17a-17b show (a) X-ray photoelectron spectroscopy of a PVP-coated and PVP-free filter membrane, and (b) The absorption angular dependence of CNT films under a linearly polarized laser beam (660 nm). As shown in FIG. 17a, the nitrogen peak can be seen clearly for type A filter membrane while absent for type B filter membrane, which confirms the surface of type B is PVP-free. Furthermore, experimentation found perfect alignment of CNT could only be achieved on type A filter membrane. A strong angular dependence of the absorption due to CNT alignment was observed, as shown in FIG. 17b. However, for CNT film made using type B filter membranes, the angular dependence of the absorption became very weak indicating the alignment of the CNT film is poor in the absence of a PVP coating.

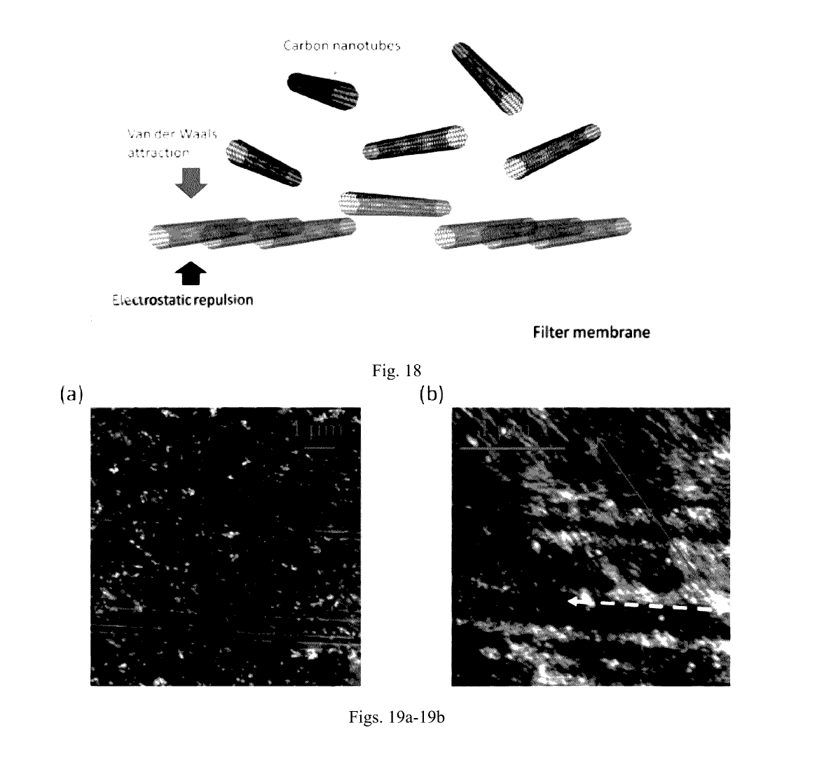

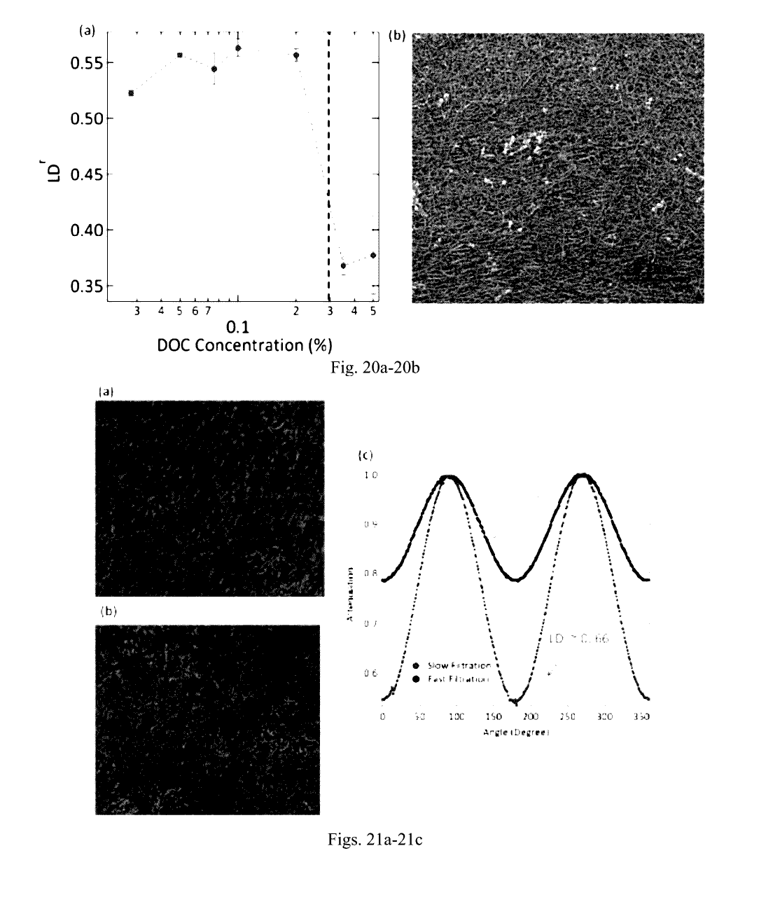

It is known that PVP molecules are polar and have strong interaction with water molecules through hydrogen bonds. This property makes a PVP-coated surfacehydrophilic. When PVP molecules interact with water, hydration shells form around the carbonyl groups of PVP. The outside of the hydration shells are covered by negatively polarized oxygen atoms. In addition, PVP molecules have strong interaction with anionic surfactants; its flexible polymer chain can effectively trap surfactants in a solution. Both the formation of hydration shells and the trap of anionic surfactants will lead to an accumulation of negative charges in the PVP layer. When negatively charged CNTs, due to the wrapping of negatively charged surfactants approaching the surface, they will face an energy barrier due to the electrostatic repulsion from the PVP layer. In the mean time, they will also feel an attraction due van der Waals forces from the surface. It is believed that the competition between these two forces can create a potential well near the surface where CNTs are confined in a narrow layer, and an ordered 2D phase appears. Without being bound by theory, it is believe the CNT alignment occurs with the same mechanism. The importance of hydrophilic PVP coating is that it makes the filter membrane surface negatively charged, allowing the formation of a potential well near the surface, which confines CNTs in a narrow layer. When CNTs can rotate in-plane and rearrange among themselves in this confined layer, a 2D nematic phase will be developed at an appropriate surface concentration (see the diagram in FIG. 18). FIG. 18 shows a schematic diagram of the formation of CNT alignment in a confined region near the surface of the filter membrane. For a PVP-free membrane, there is no electrostatic force to compete with van der Waals attraction; the absence of the potential well near the surface will make CNTs directly fall down and thus are trapped on the surface. Their in-plane motion on the surface are strongly limited due the van der Waals attraction, which then suppresses the formation of an ordered phase.

Additionally, the surface morphology of filter membrane was checked using AFM. Small shallow grooves with depths of 5 to 10 nm, widths of a few μm, and spacing of a few to tens of μm mostly along one direction on the membrane surface (FIG. 19a) were found. However, after vacuum filtration the alignment direction (red arrow in FIG. 19b) of CNTs did not follow the groove directions (dashed arrow in FIG. 19b) on the filter membrane, as shown in FIG. 19b; there was no relationship between the directions of the grooves and CNT alignment. This further indicates that the alignment happens highly likely near the surface, but not directly on the surface. FIGS. 19a-b show (a) an AFM image of filter membrane surface used in the work, and (b) AFM image of filter membrane surface after the deposition of a thin layer of aligned CNT film.

Surfactant Concentration

CoMoCAT CG200 CNTs were used to systematically investigate the influence of surfactant concentration, CNT concentration and filtration speed as discussed further herein. For this study, the concentration of CNTs was fixed at ˜15 μg/mL, and the concentration of DOC surfactant was varied from 0.03 to 0.5%. The samples were filtered at a low filtration speed as described previously. FIGS. 20a-b show (a) the LD^{r} of CNT films (CG 200) as a function of surfactant (DOC) concentration, and (b) SEM image of a film made from a CNT suspension with 0.35% DOC concentration. As shown, the LD^{r} value decreases dramatically when the concentration of DOC surfactant rises above the critical micelle concentration (CMC), which is ˜6 mM or ˜0.24% wt./vol. DOC. This result, together with an SEM image, shows that the formation of CNT alignment is strongly suppressed when the concentration of DOC is too high. Filtration being performed with the surfactant concentration above its CMC is the one of the reasons why vacuum filtration usually resulted in random CNT networks instead of aligned CNT films.

There are two possible reasons for the CNT misalignment with high surfactant concentration. Firstly, the increase of surfactants will lead to the increase of charge density in the PVP layer. This is because there will be more surfactant molecules trapped in the PVP layer, forming negatively charged micelle structures. When the electrostatic repulsion is too strong compared to van der Waals force, the potential well becomes shallow and then disappears, leading to the absence of 2D confinement. Secondly, the formation of an aligned CNT film requires the rotation of CNTs in the confined layer. The formation of micelle structures will increase the viscosity of the suspension affecting the in-plane movement of CNTs.

In addition, more insights can be obtained by comparing the results from suspension#1, 2 and 3 in table 1. In Suspension #1 (DOC) and Suspension #2 (SDBS), arc-discharge CNTs were dispersed by DOC and SDBS, respectively. Both of these surfactants are anionic, which can be trapped by the polymer chains of PVP. However in Suspension #3, CNTs are acid-functionalized; there were no anionic surfactants in the suspension. Therefore, for Suspension #3, the negative charge density on the surface of the filter paper should be smaller compared to Suspension #1 and 2, leading to a weaker electrostatic repulsion. This is likely the reason why the alignment degree was decreased in Suspension #3.

Filtration Speed

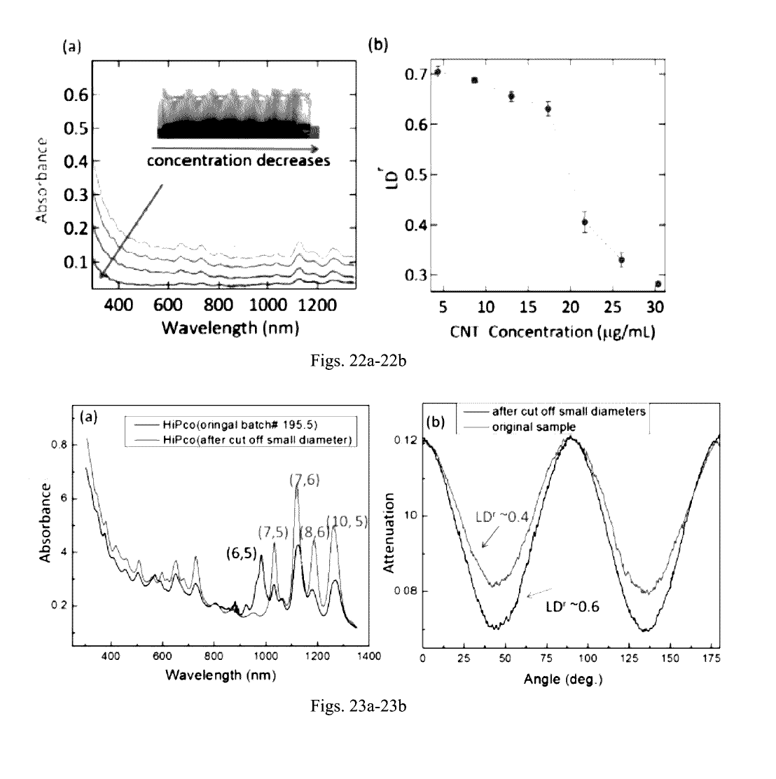

Two samples were prepared with the same CNT concentration of ˜15 μg/mL and the same DOC concentration of ˜0.045% but at two different filtration speeds (1 mL/hour and 5 mL/hour). FIGS. 21a-c show the influence of the filtration speed on CNT alignment, or more particularly (a) a SEM image of the sample at a slow filtration speed (1 mL/hour); (b) the sample at a high filtration speed (5 mL/hour); and (c) the angular dependence of CNT film absorption under a polarized laser beam (660 nm). Both SEM images and polarized absorption spectra (see FIG. 21a-c) show that the alignment quality strongly degrades with the increase of the filtration speed. Here, it is assume that the alignment is formed by the rotation of individual CNTs through interactions among neighboring tubes in the confined region. CNTs falling into the confined layer will try to follow those already aligned ones by rotating themselves. As long as there is enough time for CNTs to rearrange among themselves, the aligned structure will be able to grow layer by layer. But if the delay time between two CNTs sequentially falling onto the confined surface is too short, the formation and growth of aligned layers will be disturbed and eventually terminated. In order to examine this assumption, the delay time was estimated and compared to the CNT rotational diffusion time under the surface confinement. The delay time of CNTs on a given site can be estimated based on following expression:

$$Δ T = \frac{{VCN}_{A}}{{M}_{CNT}} \cdot {( \frac{L}{R} )}^{2} \qquad ( 3 )$$

where V is the filtration speed, C is the CNT concentration, NA is Avogadro constant, M_{CNT} is the molar mass of CNTs, L is the length of CNTs and R is the radius of the overall filtration area on the filter paper surface. For CNTs (CG200) used here, the length L is around 166 nm and diameter is around 1 nm, so the M_{CNT} is estimated around 2.4×105 g/mol based on the total number of carbon atoms in one CNT. With a CNT concentration of 15 μg/mL, the estimated delay time ΔT is around 0.19 s (0.038 s) for the filtration speed of 1 mL/hour (5 mL/hour). Based on a previous report, the rotational diffusion coefficient (DR) of CNTs with diameter of ˜1 nm is estimated to be ˜8 rad2/s when they are confined in a narrow layer. Therefore, a typical rotational diffusion time is around 0.125 s (˜1/DR). It can be seen when the speed is too fast (5 mL/hour), the delay time ΔT (0.038 s) between two CNTs depositing on the surface becomes much shorter than the CNT rotational diffusion time (0.125 s). It indicates that CNTs on the surface do not have enough time to fully align before the next nanotube deposits on top with such high filtration speed. The result is a decrease of the degree of CNT alignment, as evidenced by the experiment result.

CNT Concentration

CNT suspensions with different concentrations were prepared in the range from 4 to 30 μg/mL by diluting the parent high-concentration solution with nanopure water while keeping the concentration of DOC the same (0.05%) and below its CMC. Experimental results showed that alignment started degrading when the CNT concentration increases to a certain value. Specifically, for the CG 200 sample being used here, the transition concentration was ˜20 μg/mL as shown in FIGS. 22a-b. FIGS. 22a-b show the alignment dependence on the concentration of CNTs (CG200), or more particularly (a) absorption spectra of CNT suspensions with different concentrations (Inset: CNT suspensions with decreasing concentration from 30 μg/mL to 4 μg/mL) and (b) the LD^{r} value of aligned CNT films as a function of CNT concentration.

The phenomenon observed here is different from general 3-D liquid crystal phase transitions where a much higher concentration of CNTs (˜5 mg/mL) is required to drive the system from an isotropic phase into an anisotropic phase. However, our observation can be understood in the context of 2D nematic ordering. When an ordered phase occurs in a 2D manner, the bulk concentration does not need to be very high because of the natural accumulation of CNTs in a confined layer. In these experiments, under a steady filtration speed, individual CNTs sequentially fall into a confined layer near the surface, leading to an increase of surface density of CNTs in the confined region. Furthermore, as discussed before, the formation of alignment requires the rearrangement of CNTs. When the CNT concentration is higher, there will be more CNTs falling onto a given position in a given time interval (i.e., AT in Equation (3) decreased), which means that they cannot fully align among themselves, leading to a decrease of alignment degree.

CNT Diameters

When the above conditions are met, global alignment appears for all CNTs independent of growth methods and species, used for dispersion. However, the alignment quality varies for different species of CNTs. Within existing experimental results, the nematic order parameter, S, was more sensitive to the CNT diameter than to the aspect ratio. The SG65i sample, with the smallest diameter (0.73 nm) and the largest aspect ratio (˜525), showed a value of S around 0.75. This is much smaller than the S of the arc-discharge P2-SWNT (˜1), which had an average diameter of 1.4 nm and average aspect ratio of ˜161. Generally, large-diameter CNTs (arc-discharge and TUBALL) tended to align better than small-diameter CNTs (CoMoCAT and HiPco).

FIGS. 23a-b show (a) absorption spectra of HiPco SWCNT suspensions with (red) and without (black) the removal of small diameter tubes, and (b) the absorption angular dependence of CNT films made by original sample (red) and sorted sample (black) under a polarized laser beam (660 nm). The increasing of LD^{r} indicates the improvement of alignment in CNT films.

In order to further check the diameter influence on the degree of CNT alignment, the following test on the same batch of HiPco CNTs (batch #195.5) was performed. CNTs with diameters smaller than ˜0.8 nm were removed from the original sample by using the diameter-sorting capability of the ATPE method. Shown in FIGS. 23a-b are polarization-dependent absorption spectra of an original sample and a sample with the removal of small diameters [i.e., CNTs with diameter smaller than (7,5)]. Note that, the filtration conditions for the two samples were kept the same. The increase of LD^{r} from ˜0.4 to ˜0.6 indicates an enhancement of the degree of alignment through the removal of small-diameter CNTs.

Without being bound by theory, the diameter influence on CNT alignment is probably due to the following two reasons. Firstly, CNT diameter will influence the strength of van der Waals attraction. The smaller the diameter of an individual CNT, the weaker the van der Waals force between the CNT and the substrate is. The shape of the potential well is dependent on the subtle competition of the van der Waals attraction and the electrostatic repulsion. If the van der Waals force is too weak, the potential well will become shallow. As a result, the degree of CNT alignment will decrease due to the loss of the 2D confinement. Secondly, the stiffness of CNTs is different for different diameters, which is proportional to (CNT diameter)³. So CNTs of small diameters are much less stiff compared to CNTs of large diameters. As a result, they tend to be bent and entangled more easily in the presence of external disturbances, leading to less ideal alignment structures.

Without further elaboration, it is believed that one skilled in the art can, using the description herein, utilize the present disclosure to its fullest extent. The embodiments described herein are to be construed as illustrative and not as constraining the remainder of the disclosure in any way whatsoever. While the embodiments have been shown and described, many variations and modifications thereof can be made by one skilled in the art without departing from the spirit and teachings of the invention. Accordingly, the scope of protection is not limited by the description set out above, but is only limited by the claims, including all equivalents of the subject matter of the claims. The disclosures of all patents, patent applications and publications cited herein are hereby incorporated herein by reference, to the extent that they provide procedural or other details consistent with and supplementary to those set forth herein.

What is claimed is:

1. A method for preparing a film of rod-like nanostructures or nanotubes, the method comprising:
preparing a solution that comprises rod-like nanostructures or nanotubes, wherein the rod-like nanostructures or the nanotubes are well-dispersed so that individual rod-like nanostructures or nanotubes are separately suspended in the solution; and
performing vacuum filtration of the solution through a filtration membrane, wherein the vacuum filtration produces a film on the filtration membrane where the rod-like nanostructures or the nanotubes are aligned.

2. The method of claim 1, wherein a concentration of the rod-like nanostructures or the nanotubes in the solution is 15 μg/mL or less.

3. The method of claim 2, wherein a speed of the vacuum filtration is 1-2 mL/hour or less.

4. The method of claim 1, wherein the solution comprises a surfactant, and the surfactant has a concentration below a critical micelle concentration (CMC).

5. The method of claim 3 further comprising the step of: drying the film.

6. The method of claim 5, wherein the drying is performed by increasing a speed of the vacuum filtration to 10 mL/hour or greater.

7. The method of claim 1, wherein the film is a wafer scale film with an area of 1 cm² or greater.

8. The method of claim 1 further comprising the steps of:
transferring the filtration membrane and the film to a substrate; and
dissolving filtration membrane in solvent.

9. The method of claim 1, wherein the rod-like nanostructures or the nanotubes are single-wall carbon nanotubes (SWCNTs), multi-wall carbon nanotubes (MWCNTs), metallic carbon nanotubes, semiconducting carbon nanotubes, carbon nanotube analogs, nanowires, semiconductor nanowires, boron nitride nanotubes, or transition metal dichalcogenide nanotubes.

10. The method of claim 1, wherein the filtration membrane has pores sized from 50 to 200 nm.

11. The method of claim 1, wherein the rod-like nanostructures or the nanotubes are aligned so that central axes passing through a center of the nanotubes are approximately parallel.

12. The method of claim 1, wherein a thickness of the film is controlled by a speed of the vacuum filtration, a concentration of the rod-like nanostructures or the nanotubes in the solution, or both.

13. The method of claim 1, wherein a thickness of the film is 1 nm to 100 nm.

14. The method of claim 1, density of 10⁶ nanotubes or greater in a cross sectional area of 1 μm².

15. A method for preparing a film of rod-like nanostructures or nanotubes for an electronic device, the method comprising:
preparing a solution that comprises rod-like nanostructures or nanotubes, wherein the rod-like nanostructures or the nanotubes are well-dispersed so that individual rod-like nanostructures or nanotubes are separately suspended in the solution; and
performing vacuum filtration of the solution through a filtration membrane, wherein the vacuum filtration produces a film on the filtration membrane where the rod-like nanostructures or the nanotubes are aligned;
transferring the filtration membrane and the film to a substrate for the electronic device; and
dissolving filtration membrane in solvent.

16. The method of claim 15, wherein a concentration of the rod-like nanostructures or the nanotubes in the solution is 15 μg/mL or less.

17. The method of claim 16, wherein a speed of the vacuum filtration is 1-2 mL/hour or less.

18. The method of claim 15, wherein the solution comprises a surfactant, and the surfactant has a concentration below a critical micelle concentration (CMC).

19. The method of claim 17 further comprising the step of: drying the film, wherein the drying is performed by increasing a speed of the vacuum filtration to 10 mL/hour or greater.

20. The method of claim 15, wherein the film is a wafer scale film with an area of 1 cm² or greater.
